(19) United States
(12) Patent Application Publication
(10) Pub. No.: US 2026/0353549 A1
(43) Pub. Date: Nov. 5, 2026

(54) METHOD FOR PRODUCING AN ELECTRICAL LINE ARRANGEMENT, AND ELECTRICAL LINE ARRANGEMENT

(71) Applicant: Karlsruher Institut für Technologie, Karlsruhe (DE)

(72) Inventors: Pascal Maier, Weil im Schoenbuch (DE); Alexander Kotz, Karlsruhe (DE); Tobias Harter, Karlsruhe (DE); Alexander Quint, Karlsruhe (DE); Georg Gramlich, Karlsruhe (DE); Marius Kretschmann, Karlsruhe (DE); Thomas Zwick, Graben-Neudorf (DE); Christian Koos, Siegelsbach (DE)

(73) Assignee: Karlsruher Institut für Technologie, Karlsruhe (DE)

(21) Appl. No.: 19/141,716

(22) PCT Filed: Feb. 2, 2024
(86) PCT No.: PCT/EP2024/052567

§ 371 Date: May 26, 2026

(30) Foreign Application Priority Data
Feb. 3, 2023 (DE) 10 2023 200 908.0

(51) Int. Cl. H05K 1/02; H01Q 23/00; H05K 3/00; H05K 3/10

(52) U.S. Cl. CPC H05K 1/0227; H05K 1/0236; H05K 3/0017; H05K 3/10; H01Q 23/00; H05K 2201/09672; H05K 2201/09827; H05K 2201/10098

(57) ABSTRACT

The invention relates to a method for producing an electrical line arrangement, primarily for the microwave and/or millimetre wave frequency range, and an electrical line arrangement preferably produced by said method. The method for producing an electrical line arrangement comprises the following steps: a) producing a support structure (20), wherein at least a first subregion (120) of the support structure (20) is created by means of a freeform microstructuring method, wherein at least a second subregion (220) of the support structure (20) comprises an electrically insulating material, and wherein the support structure (20) has at least one undercut (20a, 20b, 20c, 20d, 20e, 20f, 20g, 20h) with respect to a projection direction (100); and b) producing at least one electrical line structure (1) by coating the support structure (20) with at least one electrically conductive material, wherein the coating comprises at least one spatially directed coating process, which is oriented along the projection direction (100) aligned with at least one undercut (20a, 20b, 20c, 20d, 20e, 20f, 20g, 20h). The present invention makes it possible to provide a support structure (20) with integrated undercuts (20a, 20b, 20c, 20d, 20e, 20f, 20g, 20h), in particular to produce electrical line structures (1) on substrates (40, 41) of high-frequency (HF) chips, or to produce electrical line transitions (60a-60c, 61a-61c) to already existing electrical line structures (50a-50c, 51a-51c).

### FIELD OF THE INVENTION

The invention is placed in the field of microwave technology and relates to a method for producing an electrical line arrangement, in particular for the microwave and/or millimeter wave frequency range, and an electrical line arrangement, preferably produced by said method. The present invention allows providing a support structure with integrated undercuts, particularly producing electrical line structures on substrates of high-frequency (RF) chips or electrical line transitions to already existing electrical line structures. By an appropriate design of the support structure, a wide range of differently designed electrical line arrangements can be generated.

### PRIOR ART

Standaert et al., Three techniques for the fabrication of high precision, mm-sized metal components based on two-photon lithography, applied for manufacturing horn antennas for THz transceivers, J. Micromech. Microeng. 28, 035008, 2018, describe the current state of production of RF components using two-photon lithography. In one of the methods presented there, support structures are first produced by using two-photon lithography, the entire surfaces of which are then evaporated in a PVD process. Thereafter, a thicker copper layer is formed by using electroplating. With this method, no production of insulated electrically conductive structures is possible, since the entire surface of the structure is covered by the evaporation, in particular in order to wet the entire structure uniformly by providing a “seed layer” for the subsequent electroplating. After production, the structures are positioned manually or mechanically; it is then not possible to manufacture corresponding components on substrates with other line structures.

M. Sterner et al., Electrochemically Assisted Maskless Selective Removal of Metal Layers for Three-Dimensional Micromachined SOI RF MEMS Transmission Lines and Devices”, J. Microelectromechanical Systems 20 (4), pp. 899-908, 2011, describe a method for producing an electrical line arrangement by using evaporation of a silicon covering layer which is first selectively etched with the aid of a mask, and by subsequent underetching of a silicon dioxide intermediate layer which is arranged between a silicon wafer and the silicon covering layer. In this case, the electrical line arrangements are formed on the surfaces of the silicon covering layer with direct “visual contact” to the evaporation source and remain electrically insulated from each other, since a shadow of the silicon covering layer cast onto the silicon wafer can be achieved by the underetching of the intermediate layer. This makes it possible to produce electrically conductive structures that are insulated from one another; however, due to the fixed and low height of the silicon dioxide interlayer the conductive structures generated on the surface of the silicon wafer by the direct “line of sight” to the evaporation source remain unintentionally in direct proximity to the actual line structures on the surfaces of the silicon cover layer and can, for example, electrically cross-couple. Therefore, it is imperative to remove these unwanted structures to ensure the electrical insulation of the electrically conductive structures. In addition, due to the use of a planar layer structure consisting of silicon and silicon dioxide followed by selective etching of the silicon cover layer by using a mask, this method is limited to planar line arrangements and in particular cannot provide line transitions.

A. Q. Liu, et al. “Low-loss lateral micromachined switches for high frequency applications.” Journal of micromechanics and microengineering 15.1, 2004, pp. 157-167 presents two lateral RF MEMS switches. These switches are implemented in a quasi-finite coplanar waveguide (FGCPW) configuration and are driven by an electrostatic force applied to a cantilever with high aspect ratio. The lateral switches are manufactured by reactive ion depth etching (DRIE) on a silicon-on-insulator (SOI) wafer using shadow mask technology.

EP 511360 A1 discloses an electron source which, on a substrate, contains a dielectric layer having at least one cavity in which a cathode electrode in the form of a projection is arranged, a first gate electrode which is located on the top of the dielectric layer and at least partially surrounds the cavity, and at least one second gate electrode, which is on the same side as the first gate electrode with respect to the top of the dielectric layer, wherein the first gate electrode is located between the cavity and the second gate electrode, and the two electrodes are insulated from each other, and both gate electrodes are arranged on the top of the dielectric layer, the second gate electrode being thicker than the first gate electrode.

US 2002/0167009 A1 discloses a thin-film transistor for a liquid crystal display and a method for its production, which makes it possible to reduce the number of photomasks used in a photolithography process compared to conventional methods. A passivation film is formed as a single-layer organic insulation film, and the number of exposure steps required is reduced in order to reduce the number of photomasks required, thereby improving the efficiency of the production process.

DE 10 2007 010 462 A1 discloses a method for producing a micromechanical particle beam source, which has at least one field emitter tip for the emission of particles, wherein the method comprises the following steps: —applying at least one surface layer of an electrically semiconducting or conducting material to the surface of a substrate, —structuring the at least one surface layer applied to the substrate, in such a way that the narrowest possible conducting path of low height is produced, —partially removing exposed areas of the electrically insulating substrate surface located between the paths, in such a manner that the covering of the areas of the newly formed electrically insulating substrate surface is prevented by the surface layers above it, —applying a further conductive layer to the surface thus produced, and —applying the field emitter tip to the narrow path and in doing so precisely positioning the field emitter tip with an accuracy of a few nm in the center of the optical axis of the micromechanical particle beam source.

DE 10 2020 102 372 A1 discloses a component carrier comprising a stack having at least one electrically conductive layer structure and/or at least one electrically insulating layer structure, a tapering blind hole formed in the stack, and an electrically conductive plating layer extending along at least a portion of a horizontal surface of the stack outside the blind hole and along at least a portion of a surface of the blind hole, wherein a minimum thickness of the plating layer at the bottom of the blind hole is at least 8 μm.

### OBJECT OF THE INVENTION

Based thereon, the object of the present invention is to provide a method for producing an electrical line arrangement and an electrical line arrangement, which at least partially overcome the disadvantages and limitations of the prior art.

The object of the present invention is, in particular, to enable the production of a component which has electrically conductive structures insulated from one another within a cross-sectional plane without having to remove the additional conductive structures generated in an unwanted manner by the direct “line of sight” to an evaporation source, to ensure electrical insulation of the line arrangement. Furthermore, the present invention is not intended to be limited to the production of planar line arrangements.

### DISCLOSURE OF THE INVENTION

This object is achieved by a method for producing an electrical line arrangement and an electrical line arrangement having the features of the independent claims. Advantageous refinements, which can be realized individually or in any combination, are presented in the dependent claims.

In a first aspect, the present invention relates to a method for producing an electrical line arrangement. Taken individually, the steps of the method are as follows:
a) producing a support structure, wherein at least one first subregion of the support structure is generated by using a freeform microstructuring method, wherein at least one second subregion of the support structure comprises an electrically insulating material, and wherein the support structure has at least one undercut with respect to a projection direction; and
b) producing at least one electrical line structure by coating the support structure with at least one electrically conductive material, wherein the coating comprises at least one spatially directed coating process, which is oriented along the projection direction aligned with the at least one undercut.

The term “electrical line arrangement” refers to an arrangement which is designed for the transport and/or modification of electromagnetic waves. The electrical line arrangement proposed herein comprises a support structure which has been produced in at least one first subregion of the support structure by using a free-form microstructuring method, in at least one second subregion of the support structure consisting of an electrically insulating material, and wherein an electrical line structure is applied to the support structure. In this case, the electrical line structure comprises one or more electrically conductive structures, which may also be designed in particular as electrical lines or as waveguides. The totality or a subset of the electrically conductive structures, which are electrically isolated from one another or electrically connected to one another within one or more cross-sectional planes in a defined manner, forms the desired electrical line structure. By a specific design of the plurality of the electrically conductive structures, in particular by connecting them outside a specific cross-sectional plane, this allows a plurality of different electrical line structures to be produced on the support structure, which together with the electrical line structure forms the electrical line arrangement.

The present invention relates to any kind of electromagnetic waves, provided they can be guided in an electrical line designed as a waveguide. However, electromagnetic waves with a wavelength λ of 3 μm≤λ≤1 m are preferred. In a preferred manner, electromagnetic waves
of 3 μm≤λ≤3 mm, also referred to as “terahertz waves” or “THz waves”; and/or
of 300 μm≤λ≤1 cm, referred to as “millimeter waves”; and/or
of 1 mm≤λ≤1 m referred to as “microwaves”,
   can be used.

According to method step a), the support structure is produced at least in a first subregion by using a free-form microstructuring process. Here, the term “free-form microstructuring process” refers to a three-dimensional structuring process, which comprises a subtractive or additive manufacturing process, whereby three-dimensional structures, preferably free-form structures, can be produced. In this context, a “free-form structure” is understood to mean a structure that—within the range of technical limitations with regard to resolution and accuracy—can have arbitrarily curved surfaces at least in some regions. A free-form structure thus differs in particular from structural geometries which can be produced by classical planar microstructuring processes, in particular by a combination of thin-film deposition processes, two-dimensional lithography processes (e.g. projection lithography) and etching processes on flat substrates. A combination of these processes usually leads to prism-like three-dimensional structural geometries, which each have a base and cover surface that is substantially parallel to the substrate surface, which are identical in shape or very similar to each other, and which, depending on the deposition and etching processes used in each case, are connected to each other by side walls that are either perpendicular or inclined and/or curved inwards or outwards with respect to the substrate surface. The shape of the base and cover surface is substantially determined by a mask, which is often lithographically structured, and is used for local etching or deposition. By repeating the deposition and etching processes multiple times with different masks, multi-layered structures comprising multiple prism-like sub-structures can be built up. However, the additional effort associated with this repetition is considerable and in many cases also limited by the overlay accuracy, so that the number of layers that can be produced in practice is often limited to a small number, e.g. only three. This leads to geometrical restrictions on the structures that can be produced with reasonable effort with known microstructuring methods and thus to functional restrictions of the components formed thereby.

In contrast, free-form structures produced by free-form microstructuring processes are not subject to these restrictions, or not to the same extent, since their structural geometry is not restricted to a combination of a comparatively small number of planar, prism-like sub-structures. Thus, it is possible in particular to use the subregion of the support structure defined by a free-form structure for designing an electrical line arrangement which no longer necessarily has to have a planar form. It should be noted that in many cases the free-form structures are in fact also produced from a large number of individual layers—in particular by using a multi-layer material application in 3D printing or by curing of different layers in 3D lithography processes. However, free-form microstructuring processes make it possible to choose the number of these layers to be large enough with an acceptable production effort so that a good approximation to the free-form structure is obtained and that the discretization into individual layers no longer represents a functional restriction of the structural geometries that can be produced in practice. The structures are preferably constructed from more than 10, particularly preferably from more than 20, in particular from more than 40 or 50 layers. In the production of an electrical line arrangement which is designed for a vacuum operating wavelength of approximately 1 mm, the thickness of a layer is preferably between 100 nm and 10 μm, particularly preferably between 500 nm and 5 μm, in particular between 100 nm and 1 μm. Thus, it is possible to generate electrical line structures with an accuracy of preferably better than 10 μm, particularly preferably better than 5 μm, in particular better than 1 μm. The resolution of the free-form microstructuring method is preferably better than 20 μm, particularly preferably better than 5 μm, in particular better than 1 μm. The above numerical values refer to the production of an electrical line arrangement which is designed for a vacuum operating wavelength of approx. 1 mm. For other vacuum operating wavelengths, the dimensions of the structures and thus the requirements on the accuracy and resolution of the microfabrication process used for the production can be scaled accordingly, in particular taking into account the refractive indices of the materials used. Depending on the design, the same or different free-form microstructuring processes can be used to produce the subregion of the support structure, optional additional shading structures and optional mechanical protective structures or protective layers generated by a free-form microstructuring process, wherein when the same free-form microstructuring processes are used, all structures can be generated in a common operation.

In a preferred embodiment, the free-form microstructuring process and/or a free-form microstructuring unit configured for such a process can be based on a lithographic process, which uses in particular stereolithography or direct-writing, preferably three-dimensionally direct-writing, lithography methods. Additive or subtractive manufacturing methods may be used for this, wherein the term “additive manufacturing process” refers to a production process in which material is gradually deposited on or applied to a structure, while the term “subtractive manufacturing process” describes an alternative manufacturing process in which material is gradually removed from a structure. In a preferred embodiment, the material application or the material removal can be achieved with lithographic methods using suitable photoresists, in particular negative or positive photoresists. In a preferred embodiment, surface light modulators, which allow rapid structuring, can be used in a stereolithography process. In a preferred embodiment, multiphoton lithography processes, in particular by using pulsed laser sources, can be used as direct-writing lithography methods. In this case, light pulses with a pulse duration of at most 10 ps, preferably of at most 1 ps, particularly preferably of at most 200 fs, in particular at most 100 fs, at a repetition rate of preferably at least 1 MHz, preferably of 10 MHz, particularly preferably of at least 25 MHz, in particular of at least 80 MHz, can be used. Laser light sources particularly suitable for this purpose are chosen from fiber-based femtosecond lasers or pulsed solid-state lasers, preferably titanium:sapphire lasers or diode lasers, which can be combined with frequency conversion units, in particular configured for frequency multiplication, for sum frequency generation or for differential frequency generation. In particular, depending on the lithography method used for the purpose, wavelengths in the near-infrared, visible or ultraviolet spectral range or in the range of extreme UV radiation (EUV) or the X-ray wavelengths can preferably be used. In a particularly preferred embodiment, the wavelengths can be in a range from 150 nm to 1700 nm and in particular in a range from 300 nm to 1100 nm. In the case of pulsed lasers, two-, three- or multi-photon absorption effects can be achieved by selecting the pulse duration and pulse energy. In single-photon absorption-based lithography processes using continuous wave lasers or LEDs, emission wavelengths between 360 nm and 550 nm are suitable, in particular around 365 nm, 385 nm, 405 nm, 550 nm and 532 nm. In order to increase the resolution of lithography processes, the principle of “Stimulated Emission Depletion” (STED) can be used with suitable photoinitiators in accordance with corresponding microscopy methods.

In a specific embodiment it may occur that the subregion of the support structure generated by a free-form microstructuring process, the additional shading structures, the mechanical protective structures or the protective layers are larger than the available write-field size of the machine used for the production via the free-form microstructuring process. In these cases, the structures in question can be divided into individual sections, each located within a write-field, which are produced by precise stitching these sections together. The selection of the write-field size can be made in particular by taking account of the achievable resolution, which typically improves with smaller write-fields, and of stitching errors at the write-field boundaries, the number of which can be reduced by using large write-fields. The write-field size is preferably between 50×50 μm² and 5×5 mm², particularly preferably between 100×100 μm² and 3×3 mm², and most particularly preferably between 200×200 μm² and 1×1 mm². The alignment accuracy of the individual write-fields is preferably better than 5 μm, particularly preferably better than 1 μm, in particular better than 500 nm or 100 nm. In a particular embodiment, a two-photon lithography system is used for the production. In this case, the available write-field for lenses with a numerical aperture of 1.4 and a magnification of 40, for example, may take the form of a circular surface with a diameter of 400 μm.

In certain embodiments, the first subregion of the support structure produced by a free-form microstructuring process may also comprise conductive materials. In this case, methods for 3D printing of metals can preferably be used, which can be based in particular on material extrusion, powder-bed fusion, material jetting, binder jetting, replica impression, selective laser sintering, laser metal deposition or electron beam melts. In a particularly preferred embodiment, a polymer with a high proportion of particles (slurry), selected from e.g. copper, stainless steel, or other conductive materials, can be produced. By then baking the component in an oven, the polymer compounds are opened and burned out (debinding and sintering), leaving behind a conductive workpiece that reflects to a large extent the properties of the material the particles consist of.

In addition to the subregion generated by the free-form microstructuring process, the support structure can also comprise further subregions that are not structured or are structured by other methods. Thus, cases are possible in which the support structure comprises a substantially flat substrate on which a further subregion of the support structure is generated by the free-form microstructuring process, which in isolation or together with the substrate has the undercut defined below. Suitable substrates are in particular silicon (Si), gallium arsenide (GaAs), indium phosphide (InP), aluminum oxide (Al₂O₃), beryllium oxide, quartz glass, sapphire, (woven) PTFE/glass, polyolefin, ferrite/granite or a ceramic. Furthermore, the substrate can also comprise an electrically conductive subregion. During coating of a support structure comprising a substrate, it may be possible in particular that the at least one exposed surface defined by the at least one undercut in the support structure, which is designed to insulate the adjacent electrically conductive structures, can be arranged on the substrate and is not arranged, for example, on the subregion of the support structure produced by the free-form microstructuring process or on the subregion of the support structure consisting of an insulating material.

The support structure produced according to method step a) further comprises at least one second subregion comprising an electrically insulating material, which
on the one hand, provides a mechanically stable and, at least in some regions, electrically insulating basis for a subsequent coating, which is carried out according to method step b), with the at least one electrically conductive material; and
on the other hand, can be brought into a desired geometric, not necessarily planar shape on which the desired electrical line structure is formed by the coating taking place according to method step b).

For the purposes of the present invention, “electrically insulating material” refers to a substance the electrical conductivity σ of which is not more than 10⁻⁴ S/m, preferably not more than 10⁻⁷ S/m, in particular not more than 10⁻¹⁰ S/m. In addition, the electrically insulating material preferably has a high dielectric strength and preferably low losses, in particular in the form of a low loss factor tan S of not more than 0.1; preferably not more than 0.05; in particular not more than 0.01 at the respective operating frequency of the electrical line structure. In this case, the term “operating frequency” refers to a frequency of the electromagnetic wave for which a selected electrical line arrangement is preferably designed. In an analogous manner, the term “operating wavelength” is specified as the wavelength of the electromagnetic wave for which a selected electrical line arrangement is preferably designed. Suitable materials for the at least one electrically insulating subregion of the support structure are preferably ceramics, glasses, polymers or other organic compounds or appropriately doped semiconductors as well as composite materials made of these materials. In particular, suitable materials are those that can be three-dimensionally structured by appropriate methods, wherein in a preferred embodiment, the methods and the associated materials are selected in such a way as to make the production of free-form structures possible. In a preferred embodiment, polymer-based materials are used for producing the support structure, which preferably contain an optically additively or subtractively structurable polymer, e.g. from the class of acrylates, an epoxy resin or a fluoropolymer. If in method step a) a lithographic method is used for structuring a polymer-based material, polymers can preferably be used, which in particular may be fluorinated or may have polysiloxane-based components.

In a particularly preferred embodiment, the first subregion produced in method step a) by a free-form microstructuring process can be identical to the second subregion comprising the electrically insulating material. However, the two regions can also be disjoint or non-intersecting, or they may completely or partially mutually comprise each other. An example in which the second subregion completely comprises the first subregion results when an electrically conductive region of the substrate is replaced by an insulating substrate, so that only the insulating second subregion was generated by 3D printing. In another example, in which the two regions are disjoint, the support structure has a metallic core comprising a metallic substrate and an insulating coating. The core filling the first subregion is generated in the first subregion of the support structure by a free-form microstructuring process, while an insulating coating can be applied in the second subregion of the support structure independently thereof in a subsequent process, in particular by an isotropic coating method. In this example, the two subregions are thus disjoint.

According to method step a), the support structure is produced in such a way that it has at least one undercut with respect to a projection direction. The term “undercut” refers to an overhang defined with respect to a projection direction, which is introduced into the surface of the support structure. A geometrical definition of the term “undercut” is illustrated by way of example in FIG. 3, which shows a support structure with an undercut defined with respect to a projection direction p with an associated shaded area. The shaded area comprises the totality of all points P on the surface of the support structure, for which a half-line g, emanating from point P and oriented opposite to the projection direction p, cuts through the support structure. The totality of the portions of all such half-lines g located inside the support structure defines the subregion of the support structure referred to as overhang. The overhang defines a shaded region, which comprises the totality of the connecting lines PP′ of the points P lying outside the support structure to the entry point P′ of the associated half-line g into the support structure located nearest to it opposite to the projection direction p.

The at least one undercut is designed to generate a shadow in at least one spatially directed coating of the support structure, applied along the projection direction, with at least one electrically conductive material. The term “shadow” refers to a result of the coating of the support structure with the at least one electrically conductive material, whereby at least one exposed area on the surface of the support structure remains uncoated and is not covered by the electrically conductive material. Depending on the design of the coating process according to method step b) and depending on the direction of the spatially anisotropic material flow, the uncoated region can be identical with the region shaded in the geometrical sense, at least enclose some regions of the shaded region, or be a part of the shaded region.

According to method step b), the electrical line structure is produced by coating the support structure with at least one electrically conductive material. In a particular embodiment, the coating of the support structure may involve a plurality of coating methods and/or materials, at least one coating method being spatially directed and wherein at least one material must be electrically conductive in the sense defined herein. In a preferred embodiment, the at least one electrically conductive material is applied in a directed coating process.

A coating process suitable for the purpose can be used for coating the support structure. The coating process can preferably be selected from a process of physical vapor deposition (PVD), in particular thermal evaporation, electron beam evaporation, laser beam evaporation, arc evaporation, molecular beam epitaxy, ion plating or sputter deposition, wherein the sputter deposition comprises DC sputtering, RF sputtering, magnetron sputtering, reactive sputtering, ion beam sputtering or atomic beam sputtering; or from a chemical vapor deposition (CVD) process including plasma-assisted chemical vapor deposition (PECVD), thermal injection, or electroplating. In these methods, the degree of spatial anisotropy, i.e. the directedness of the material transport during the coating process, can be adjusted by using various parameters, in particular the pressure under which the coating is carried out. In addition to spatially anisotropic, i.e. directed coating processes, isotropic processes can also be used, in which the structures are coated on all sides. A wide range of processes are conceivable here, such as immersion or spraying processes, spin coating, atomic layer deposition (ALD) or galvanic processes. In a particular embodiment, after a directed coating with a metal, an isotropic coating with an inert protective material can be applied, in particular to prevent oxidation of the metal areas. In a particular embodiment, the thickness of the applied electrically conductive structures of the electrical line structure from the at least one electrically conductive material can be increased by galvanic growth in order to increase the robustness of the coating, in particular under mechanical stress. In this case, the achieved thickness of the electrical line structure can preferably be greater than 1 μm, particularly preferably greater than 10 μm, in particular greater than 20 μm or 50 μm. The achieved thickness can be adjusted in particular by setting the process parameters such as current density, temperature and time for the respective material.

For the purposes of the present invention, “electrically conductive material” refers to a substance the electrical conductivity a of which is preferably at least 10⁶ S/m, particularly preferably at least 10⁷ S/m, in particular at least 5×10⁷ S/m. Materials that are particularly suitable for this purpose include silver, copper, gold and aluminum; however, other metals may also be used. In this case, the electrical line structure may comprise a uniform region of a single electrically conductive material, a mixed phase consisting of at least two electrically conductive materials different from one another, in particular an alloy of at least two metals which are different from one another, and/or a layer structure consisting of at least two layers different from one another, each comprising a uniform phase or a mixed phase.

In a preferred embodiment, a sequence of the layers in the layer structure can be selected in a preferred manner. A preferred layer sequence may comprise in particular a first layer directly or indirectly adjacent to the support structure, which has an adhesion promoter with good adhesion properties with respect to a substrate arranged underneath and/or a layer arranged above, wherein the first layer may comprise in particular titanium, a core of a material with high conductivity, preferably copper or gold, and an outer passivation layer adjacent to the surroundings made from a chemically resistant, non-oxidizing material, preferably gold, silicon nitride or silicon dioxide. In addition, at least one further layer, preferably titanium, can be introduced for diffusion protection between the material of the core and the passivation layer. The use of other materials is also possible. Thus, the electrical line structure can be designed simultaneously for a particularly high charge transport and for a particularly high resistance to the environment in which substances that are aggressive to the electrically conductive material can occur, in particular oxygen. The application of these layers does not necessarily need to be carried out in a spatially directed process. Thus, it may be helpful in particular for the passivation layer to use an isotropic process that protects the electrical line arrangement from multiple sides, preferably from all sides, in particular atomic layer deposition or evaporation under high pressure.

A conductive layer thickness γ of the electrical line structure can in many cases be approximated based on the skin effect and by taking into account the vacuum operating frequency, in particular using equation (1):

$$γ = \frac{1}{\sqrt{μπ}} \frac{1}{\sqrt{σ f}} \qquad ( 1 )$$

Here, the conductive layer thickness γ is defined as the resulting wall thickness of a notional round conductor which has the same resistance for direct current as a solid conductor due to the skin effect at a frequency f. The absolute permeability μ=μ₀ μᵣ consists of the permeability constant μ₀=1,256·10⁻⁶ N/A² and the relative permeability coefficient μᵣ of the electrically conductive material used for the round conductor. The electrical conductivity of the electrically conductive material is referred to by σ. For example, for copper, at a vacuum operating wavelength of approximately 1 mm and an electrical conductivity σ=5.8·10⁶ S/m, a conductive layer thickness of γ=0.12 μm is obtained. The layer thickness of the electrically conductive material when deploying the coating process is therefore preferably selected at least of sufficient size that the layer thickness is preferably three times, in particular preferably five times, in particular ten times, the conductive layer thickness at the desired operating frequency or the desired operating wavelength. For other operating wavelengths, the layer thicknesses can be scaled in proportion to the root of the wavelength, taking into account the conductivity of the electrically conductive materials used.

According to method step b), the coating of the support structure comprises at least one spatially oriented coating process, which is oriented along the projection direction aligned to the at least one undercut. As a result, the electrically conductive material is applied on the support structure as an electrical line structure in the form of one or more electrically conductive structures, which are electrically isolated from one another or electrically connected to one another in a specified manner within a cross-sectional plane, wherein the direction of the coating corresponds to a projection direction related to the undercut. The at least one undercut introduced into the support structure, as described above, results in the formation of at least one uncoated exposed area on the surface of the support structure, which provides electrical insulation at desired locations on the surface of the support structure between the electrically conductive structures adjacent to the at least one exposed area. In this way, the desired electrical line structure is formed on the surface of the support structure, comprising the multiplicity of the electrically conductive structures which are electrically isolated from one another or electrically connected to one another in a defined manner within a cross-sectional plane. In this case, it is particularly advantageous if the at least one undercut is generated during method step a), with appropriate knowledge of the desired projection direction during method step b), in particular such that via the shape of the support structure and the at least one undercut introduced therein, the final form of the desired electrical line structure, which comprises the multiplicity of the electrically conductive structures electrically isolated from one another or electrically connected to one another in a defined manner, taking into account the direct line of sight between each point P on the support structure to be coated and the location of the evaporation source from which the electrically conductive material used for coating the support structure is provided, is freely defined in space.

In a preferred embodiment, the method of physical gas-phase vapor deposition (PVD), in particular electron or laser beam evaporation, can be used. In this case, by choosing a sufficient working distance between the location of the evaporation source and the support structure to be coated, to a good approximation an evaporation direction defined by the connecting line between the evaporation source and the support structure to be coated can be set, which corresponds to the desired projection direction related to the undercut according to the invention. In this case, the distance between the evaporation source and the support structure to be coated is preferably more than 25 cm, particularly preferably more than 50 cm, in particular more than 75 cm or 100 cm, so that the flow of the evaporation beams originating from the evaporation source around the defined projection direction at the location of the support structure to be coated has a divergence of preferably less than 10°, particularly preferably less than 5°, in particular less than 2°. The term “divergence” at the location of the support structure to be coated is understood to mean the variance or standard deviation of the directions under which the beams emitted from an evaporation source impact at a certain point of the support structure. The variance can be determined in particular from the ratio of the lateral extent of the evaporation source to a distance of the evaporation source from the support structure to be coated. A large variance in the direction of the incident beams can usually lead to a corresponding blurring of the edge of the shadow cast by the at least one undercut, which can be accompanied by adverse effects with regard to the properties of the electrical line arrangement to be generated. A deviation between the actual evaporation direction and a desired projection direction relative to the undercut according to the invention can preferably be at most 20°, particularly preferably at most 10°, and in particular at most 5° or 2°. A working pressure in the chamber of the coating system can preferably be selected such that a mean free path length of the particles transferred during the evaporation exceeds the distance between the evaporation source and the support structure to be coated. The term “mean free path length” refers here to a path length that a particle, in particular one of either an atom, molecule, ion or electron, travels on average in a given material before it comes into collision with another particle. If a particle stream in a material has traveled the mean free path length, then a fraction 1/e of the particle stream has not yet undergone a collision with another particle. The mean free path length preferably exceeds the distance between the evaporation source and the support structure to be coated by a factor of at least 3, particularly preferably by a factor of at least 8 or 20, in particular by a factor of at least 100 or 200. The pressure can typically assume a value of from 10⁻⁷ Pa to 10⁻³ Pa, in particular depending on the material selected.

In a particular embodiment, in carrying out the method step b) not only can the desired electrical line structure be formed, but also at least one other electrically conductive structure can be generated, which is not necessarily a functionally relevant component of the desired electrical line structure. In this case, it is therefore desirable if the at least one undercut is designed such that the at least one other electrically conductive structure can be arranged at a sufficiently large distance from the desired electrical line structure. In such an arrangement, the influence of the additionally generated electrically conductive structure on the electromagnetic wave guided in the desired electrical line structure, which can also be referred to as the “mode”, can preferably be minimized. In particular, in order to avoid coupling a mode guided in the desired electrical line structure with at least one other electrically conductive structure, a distance between the two structures can be set which is of sufficient size as to exceed a penetration depth E of the electromagnetic wave guided in the desired electrical line structure into the surrounding spatial region, preferably by at least double, particularly preferably five times, in particular ten times, the penetration depth E. The term “penetration depth E” refers here to a depth at which an evanescent electric field associated with a mode guided in an electrical line structure has fallen by a factor of 1/e.

The method described herein allows a wide range of different electrical line structures to be generated on a support structure.

In a preferred embodiment, the electrical line structure may comprise a single microstrip line which is formed from an electrically conductive structure that is electrically insulated from the environment in all cross-sectional planes along the electrical line structure. Electrical insulation of the electrically conductive structure against the environment can be preferably achieved by the at least one exposed area on the surface of the support structure, which remains uncoated during the coating step due to the shadow cast by the at least one undercut. The electrically conductive structure may be implemented on the support structure in particular as an electrical line or as a waveguide.

In a further preferred embodiment, the electrical line structure may comprise at least two electrically conductive structures, which, spatially separated from each other, are arranged spaced apart on the support structure and at the same time can be electrically insulated from each other in all cross-sectional planes along the electrical line structure. In this case, the at least two electrically conductive structures can preferably be spatially separated from one another and electrically insulated from one another by the fact that the at least one exposed area generated by the at least one undercut is arranged between the at least two electrically conductive structures.

In this embodiment, the electrical line structure can comprise a plurality of individual electrically conductive structures, electrically insulated from one another, in the form of a multiplicity of microstrip lines. The at least two insulated microstrip lines can be at the same electrical potential or at different electrical potentials. For example, the microstrip lines can be arranged parallel to one another. However, other configurations of the microstrip lines are conceivable.

In this embodiment, the electrical line structure may be or comprise, in particular, a slotted line, wherein the slotted line has two electrically conductive structures which are spatially separated from each other and electrically insulated from each other in all cross-sectional planes along the electrical line structure, wherein the two electrically conductive structures are at the same electrical potential.

In this embodiment, the electrical line structure (1) may be or comprise a coplanar line, wherein the coplanar line has three electrically conductive structures which are spatially separated from one another and electrically insulated from one another in all cross-sectional planes along the electrical line structure, wherein two of the electrically conductive structures are at the same electrical potential, while a third of the electrically conductive structures is at a different electrical potential.

In a further preferred embodiment, the electrical line structure may be designed in the form of an antenna. In this embodiment, the electrical line structure may preferably comprise a plurality of individual electrically conductive structures electrically insulated from one another within a cross-sectional plane, which are varied along the line structure in a defined manner and in particular can also be electrically connected in a defined manner within at least one further cross-sectional plane of the electrical line structure. In this embodiment, at least one exposed area generated by the at least one undercut may be configured in particular to enable a transition of a line-bound electrical signal to a free-space wave.

In a further preferred embodiment, the electrical line structure may comprise, in addition to the desired electrically conductive structures within a cross-sectional plane, at least one further electrically conductive structure described in more detail above, in particular to enable certain functions. In this configuration, the electrical line structure may be designed in particular in the form of an electrical line coupler. The electrical line coupler may comprise two electrically conductive structures in the form of two waveguides, which are arranged spaced apart on the support structure and can be electrically insulated from each other in all cross-sectional planes along the line structure, wherein the two waveguides guide different signals and are a mutual distance from each other, so that a desired coupling of an electric field from one electrically conductive structure to the other electrically conductive structure can be adjusted via at least one further electrically conductive structure.

In a further preferred embodiment, the electrical line structure may be embodied in the form of an electrical probe tip, which is suitable for contacting electrical circuits, in particular radio frequency (RF) circuits, and which can preferably have at least one contact element for this purpose. By a suitable shaping of the support structure to be coated, the at least one contact element can be configured as a contact tip or be based on suitable structural elements projecting in a direction perpendicular to the coated surface, which allow a geometrically precise contacting of corresponding contact surfaces (pads or probe-pads) on a chip or a flat substrate.

The method described herein can be used to produce further electrical line structures that have special geometries or can be suitable for special purposes.

A particular advantage of the method described herein is that the at least one undercut can allow the support structure for the electrical line structure to be designed in such a way that, based on the electrically conductive material of the electrical line structure and the geometry of the support structure, an effective permittivity of the mode guided in the electrical line structure can be set and varied along the line structure or the propagation direction of the electromagnetic field that exists in the line structure. The effective permittivity of the mode guided in the at least one electrical line structure along the direction of propagation of the mode perpendicular to the respective drawing plane is preferably set to 20Ω to 100Ω. Such a type of configuration may be particularly advantageous to reduce the influence of a high dielectric constant, for example of a substrate, for an antenna by gradually leading the mode that is guided in the electrical line structure away from the substrate, in particular by variation of the at least one undercut along the line structure. This allows the permittivity effectively detected by the mode to be adapted to the local conditions in order to reduce line loss or gradually adjust the line impedance. Here, the term “gradually” refers to a continuous transition of a characteristic quantity of a mode, in particular the impedance, preferably starting from a substrate with high dielectric constant to a subregion of the support structure based on a material with lower dielectric constant, in particular by a linear transformation of the geometries at the transitions.

In a further embodiment, the method described herein can be used to provide at least one electrical line transition to at least one already existing electrical line structure, which was previously produced by using the method described herein and/or by using conventional manufacturing methods on a substrate. For this purpose, the support structure can be aligned to the electrical line structure already present, in such a way that the coating of the support structure with the at least one electrically conductive material takes place along the projection direction that is aligned to the at least one undercut, such that the at least one electrical line transition from the already existing electrical line structure to the developing electrically conductive structure of the electrical line structure is produced. The support structure can thus ensure by using the at least one undercut that the existing electrical line structure remains electrically insulated in all cross-sectional planes along the line structure.

However, in this type of coating, a global covering of the substrate outside the subregion of the support structure produced by a free-form microstructuring process by using the electrically conductive material can occur, whereby the already existing electrical line structure as well as other components or circuits present on the substrate can be coated undesirably. In order to prevent such an undesirable coating, at least one additional shading structure can be aligned to the at least one electrical line transition between the already existing electrical line structure and the electrical line structure newly fabricated by using the method described herein, in such a way that the existing electrical line structure can remain electrically insulated in all cross-sectional planes along the line structure during the coating under the projection direction. This also prevents global short circuits of the electrical line structure to further electrically conductive structures being deposited.

In a preferred embodiment, the at least one additional shading structure can cover further surfaces of the substrate in such a way that these further surfaces of the substrate remain protected from a global covering with the electrically conductive material. For this purpose, it is in particular conceivable to completely cover these further surfaces with a protective structure, in particular in the form of a protective layer, and thus to minimize the influence of the developing electrical line structure on the existing electrical line structure on the substrate by a sufficient thickness of the protective structure, in particular the protective layer. Alternatively, additional protective structures or shading structures, in particular a protective layer, can be optionally removed after the coating, in particular by simply peeling them off using a suitable tool, preferably a pair of tweezers, or by using a lift-off process, which thereby allows the global covering with the electrically conductive material to prevent the further electrically conductive structure formed as a by-product from being detached again. Preferably, a selective covering of the regions to be protected with a protective layer can be carried out before the coating. In a preferred embodiment, the selective application of the protective layer can be carried out by inkjet printing, using a dispenser and/or by a lithographic structuring. After application of the electrically conductive material, the protective layer can be removed again and hence also the further electrically conductive structure formed on the protective layer, in order to expose the already existing electrical line structure again. It is advantageous in this case if neither the protective materials used nor any substances used for their removal, such as solvents, damage or otherwise adversely affect the support structure, in particular the subregion produced by the free-form microstructuring process, during prolonged exposure. In a preferred embodiment, PMMA (polymethyl methacrylate) or another suitable substance can be used as a protective material for the protective layer, which can be removed again with PGMEA (propylene glycol monomethyl acetate) without affecting other areas of the support structure which were manufactured by using two-photon lithography. Advantages of such lift-off processes include a faster global covering of the substrate, in particular by using a deposition process, if the manufacture of the protective structure or shading structures cannot be carried out by using a free-form microstructuring process due to the size of the surface to be covered.

In a further preferred embodiment, the electrical line structure may comprise at least two electrical line transitions and thus be configured as a connecting element between at least two line structures arranged on separate substrates, the line structures having been produced previously by using the method described herein and/or by using conventional manufacturing methods. The support structure can comprise at least two substrates mounted on a common base plate and the at least one subregion produced by using the free-form microstructuring process, which can connect via the electrical line transitions to the existing line structures on the two substrates, which have the at least one undercut according to the invention with respect to the projection direction. To protect the surfaces of the two substrates, these can be provided again at least in some regions with corresponding temporary or permanent protective structures during the coating process in method step b), in particular shading structures or protective layers.

In a further preferred embodiment, the electrical line structure may be embodied in the form of an interdigital capacitance. The electrical line structure in the form of the electrical interdigital capacitance can comprise a plurality of electrically conductive structures, which can be arranged substantially alternately in two different planes running parallel to each other and wherein these can be at different potentials. Preferably, the electrically conductive structures can lie in a common first plane defined by recesses in the support structure, while the remaining electrically conductive structures can lie in a second plane defined by webs between the recesses. To produce the electrical line arrangement the at least one undercut is introduced into the support structure with respect to the projection direction, whereby the at least one exposed area ensures an electrical insulation of the electrically conductive structures applied on the two different planes. In a preferred embodiment, a divergence of the evaporation beams emanating from the evaporation source around the defined projection direction at the location of the support structure to be coated can be used to increase the width of the strip-like electrically conductive structures generated in the first plane so that in a projection along the projection direction, they can overlap with the electrically conductive structures in the second plane. This can contribute in particular to increasing the electrical capacitance between the structures on the two planes. Electrically conductive structures located in a common plane can be electrically connected to one another in a further cross-sectional plane of the electrical line structure and thus form a common electrical supply line. Due to the design of the subregion of the support structure as a 3D free-form structure, this design can offer more degrees of freedom in the arrangement in comparison to methods from the prior art, in particular with improved resolution.

In a further aspect, the present invention relates to an electrical line arrangement, in particular an electrical line arrangement which was produced by using the method also described herein. The electrical line arrangement comprises:
a support structure comprising
   at least one first subregion, designed as a three-dimensional free-form structure and produced using a free-form microstructuring process, and
   a second subregion comprising an electrically insulating material,
wherein the support structure has at least one undercut with respect to a projection direction; and
at least one electrical line structure, applied on the support structure as a coating by using at least one spatially directed coating process with at least one electrically conductive material along the projection direction aligned to the at least one undercut.

For further details with regard to the present electrical line arrangement, reference is made to the description of the method for producing an electrical line arrangement also described herein, as well as to the exemplary embodiments.

The terms “have”, “exhibit”, “comprise” or “include” or any grammatical forms thereof are used in a non-exclusive manner. Accordingly, these terms may refer both to situations in which, in addition to the features introduced by these terms, there are no other features present, as well as to situations in which one or more other features are present. For example, the expression “A has B”, “A exhibits B”, “A comprises B” or “A includes B” may refer both to the situation in which, apart from B, there is no other element present in A (i.e., a situation in which A consists exclusively of B), as well as to the situation in which, in addition to B, one or more other elements are present in A, for example element C, elements C and D or further elements.

It should also be noted that the terms “at least one” and “one or more” and grammatical forms of these terms, when used in connection with one or more elements or features and intended to express the fact that the element or feature may be provided once or multiple times, are usually only used once, for example when the feature or element is first introduced. When the feature or element is later mentioned again, the corresponding term “at least one” or “one or more” is generally no longer used, without limiting the possibility that the feature or element may be provided once or multiple times.

Furthermore, the terms “preferred”, “preferably”, “in particular”, “for example” or similar terms are used herein in conjunction with optional features without thereby limiting alternative embodiments. Thus, features introduced by these terms are optional features, and it is not intended to restrict the scope of protection of the claims, and in particular of the independent claims, by these features. Thus, as a person skilled in the art will recognize, the invention can also be carried out using other embodiments. Similarly, features introduced by “in one embodiment of the invention” or “in one exemplary embodiment of the invention” are understood as being optional features without thereby limiting alternative embodiments or intending to limit the scope of protection of the independent claims. Furthermore, these introductory expressions are intended to leave open all possibilities of combining the features introduced by them with other features, whether optional or non-optional.

### Advantages of the Invention

In contrast to known methods for producing electrical line arrangements, which are often based on the use of masks and are therefore essentially limited to planar support structures and the production of different heights of the electrical line arrangements, the present method does not require masks for manufacture. In particular, this enables the production of 3D free-form line structures. The use of 3D printing techniques for producing the support structures allows the production of complex three-dimensionally configured support structures, which are suitable in particular for increasing the coupling efficiency and the bandwidth between transmission lines compared to known methods. Due to the use of free-form microstructuring methods for the production of free-form support structures, no mask is necessary for the production, and the electrical line arrangements can in particular also be produced in situ, i.e. directly at the usage site on e.g. chips. This allows the electrical line arrangements to be aligned directly on existing circuits and electrically connected with e.g. large bandwidth and low losses, wherein in particular the precise assembly steps that are usually necessary are eliminated. This enables the implementation of a wide variety of components, comprising connecting elements between multiple chips or even antennas, which are designed as a free-form structure for more efficient radiation and are spaced apart from the surface.

From the prior art cited at the beginning, no first subregion of the support structure is known which is generated by using a free-form microstructuring process. Therefore, the cited prior art also does not disclose the production of non-planar electrical line arrangements as specified in the present invention. In particular, the present invention solves the problem of producing a component which has electrically conductive structures insulated from one another within a cross-sectional plane without first having to remove the additional conductive structures generated in an unwanted manner by the direct “line of sight” to an evaporation source, to ensure electrical insulation of the desired line arrangement. In further differentiation from the prior art cited above, the present invention thus also solves problems with regard to so-called packaging for the next generation of radio-frequency components, which are designed in particular for millimeter waves and THz frequencies.

By using the present production method, microwave components, in particular antennas, chip-to-chip connecting elements or electrical probe tips can, in addition, be produced directly on existing substrates as support structures. The printing of the subregions of the support structure defining the electrical line structures or also on a substrate contained in the support structure and the protection of the support structure or also the substrate by using shading structures, in particular protective layers, enables a wide variety of implementable structures with 3D free-form geometries and allows, in particular, the electrical line structures to be adapted to the conditions of existing structures. This is particularly important in radio-frequency technology, since changes to electrical line structures on chips are typically time-consuming and costly, while the function and design of the electrical line structures according to the invention can be varied in a flexible way by a suitable shaping of the subregion of the support structure generated by using a free-form microstructuring process. The possibility of the three-dimensional design of the support structure, for example, means that electromagnetic waves can be guided away from the substrate and thus the influence of a high dielectric constant of the substrate or the support structure can be easily adapted to the local requirements within a cross-sectional area as required. Similarly, electrical probe tips with a wide variety of geometries can be implemented flexibly on standardized and thus cost-effective support substrates.

### BRIEF DESCRIPTION OF THE DRAWINGS

Further details and features of the invention can be found in the following description of preferred exemplary embodiments, in particular in connection with the dependent claims. In the text, the respective features can be realized either in isolation or in combination with one another. The invention is not limited to the exemplary embodiments. The exemplary embodiments are shown schematically in the following figures. In these, the same reference numbers in the figures refer to identical or functionally identical elements or to elements that correspond in terms of their functions. Taken individually, in the drawings:

FIGS. 1 and 2 each shows a preferred exemplary embodiment of a method according to the invention for producing an electrical line arrangement as a schematic cross-sectional drawing;

FIG. 3 shows schematically a geometric definition of the undercut according to the invention with respect to the projection direction in the support structure according to the invention;

FIGS. 4 to 10 each shows an exemplary embodiment of the electrical line arrangement according to the invention as a schematic cross-sectional drawing;

FIGS. 11 to 14 show schematically a method sequence for producing a further electrical line arrangement according to the invention;

FIGS. 15 and 16 each shows a preferred exemplary embodiment of the electrical line arrangement according to the invention;

FIG. 18 shows a further exemplary embodiment of the method sequence for producing a further electrical line arrangement according to the invention as microscope images; and

FIGS. 19 and 20 each shows a further exemplary embodiment of the electrical line arrangement according to the invention as microscope images.

### DESCRIPTION OF THE EXEMPLARY EMBODIMENTS

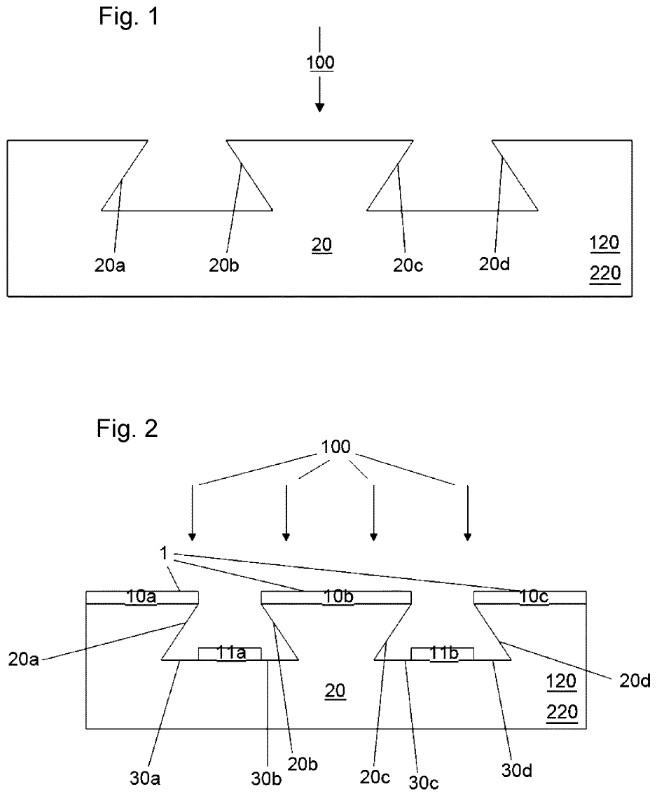

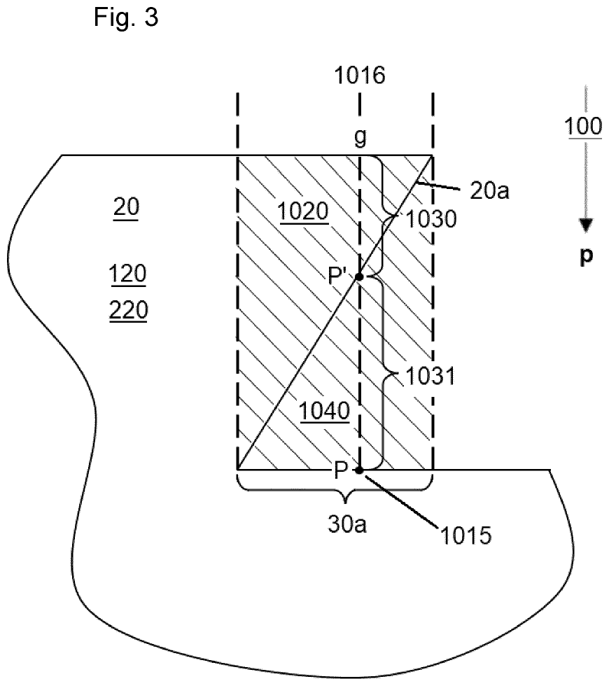

FIGS. 1 and 2 each shows, in form of a schematic cross-sectional drawing, a preferred exemplary embodiment of a method according to the invention for producing an electrical line arrangement. Here, FIG. 1 schematically represents method step a) and FIG. 2 schematically represents method step b). The illustrations selected for this purpose and the shapes used, in particular for the support structure 20, are to be understood as examples; according to expert considerations, a wide variety of other arrangements and shapes are possible.

FIG. 1 shows schematically method step a), which comprises the production of the support structure 20, wherein a first subregion 120 of the support structure 20 is generated by using a free-form microstructuring method, wherein a second subregion 220 of the support structure 20 comprises an electrically insulating material, and the support structure 20 has undercuts 20a, 20b, 20c, 20d with respect to a projection direction 100. In the case outlined, the subregions 120, 220 are identical and form the support structure 20.

FIG. 2 schematically illustrates method step b), which relates to the production of at least one electrical line structure 1 by coating the support structure 20 with at least one electrically conductive material along a projection direction 100 aligned to the undercuts 20a, 20b, 20c, 20d. In this step, the coating of the support structure 20, including the undercuts 20a, 20b, 20c, 20d included in the support structure 20, is carried out from the projection direction 100. The regions 30a, 30b, 30c, 30d shaded with the undercuts 20a, 20b, 20c, 20d present in the support structure 20 result from the defined projection direction 100 known in advance and are not or only insignificantly affected by the spatially directed coating of the support structure 20 by using the electrically conductive material. In this context, the wording “only insignificantly” means that although edge regions of the shaded regions 30a, 30b, 30c, 30d, for example due to a non-vanishing divergence 105 of the evaporation beams emitted from the evaporation source around the defined projection direction 100, can be covered by the electrically conductive material, an exposed area 30a, 30b, 30c, 30d uncovered by the electrically conductive material still remains, however, which gives rise to an electrical insulation of the electrically conductive structures 10a, 10b, 10c in the sketched cross-sectional area of the line structure 1.

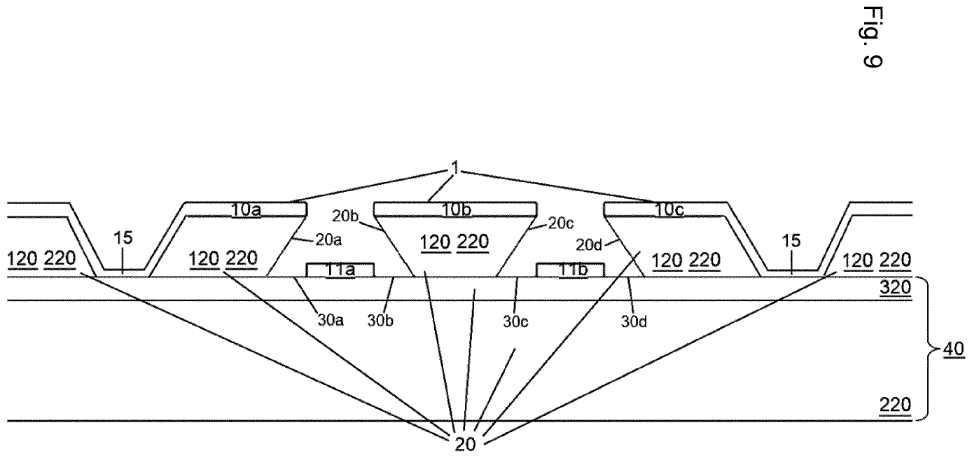

As schematically illustrated in FIG. 2, a plurality of electrically conductive structures 10a, 10b, 10c and other electrically conductive structures 11a, 11b are formed on the surface of the support structure 20 by the coating with the electrically conductive material within a cross-sectional plane. In the present exemplary embodiment according to FIG. 2, three electrically conductive structures 10a, 10b, 10c are located at a common height and each have a shape which is predetermined by the three-dimensional shape of the surface of the support structure 20. Due to the undercuts 20a, 20b, 20c, 20d included in the support structure 20, exposed areas 30a, 30b, 30c, 30d are additionally formed on the surface of the support structure 20 by the coating of the surface of the support structure 20 with respect to the projection direction 100 with the electrically conductive material. The exposed areas 30a, 30b, 30c, 30d insulate the electrically conductive structures 10a, 10b, 10c from one another and are further designed so that the electrically conductive structures 10a, 10b, 10c remain electrically insulated within a cross-sectional plane from the additional electrically conductive structures 11a, 11b which have inevitably formed in the recesses of the support structure 20 during the performance of method step b). By an appropriate shaping of the support structure 20, a configuration can be achieved in which the additional electrically conductive structures 11a, 11b are so far removed from the electrically conductive structures 10a, 10b, 10c that an electrical signal conducted by the electrically conductive structures 10a, 10b, 10c does not interact with the other electrically conductive structures 11a, 11b, see also FIG. 6 and the associated description. In this case, the three electrically conductive structures 10a, 10b, 10c form the desired electrical line structure 1. The electrical line structure 1, together with the support structure 20 and the exposed areas 30a, 30b, 30c, 30d present here, forms the electrical line arrangement.

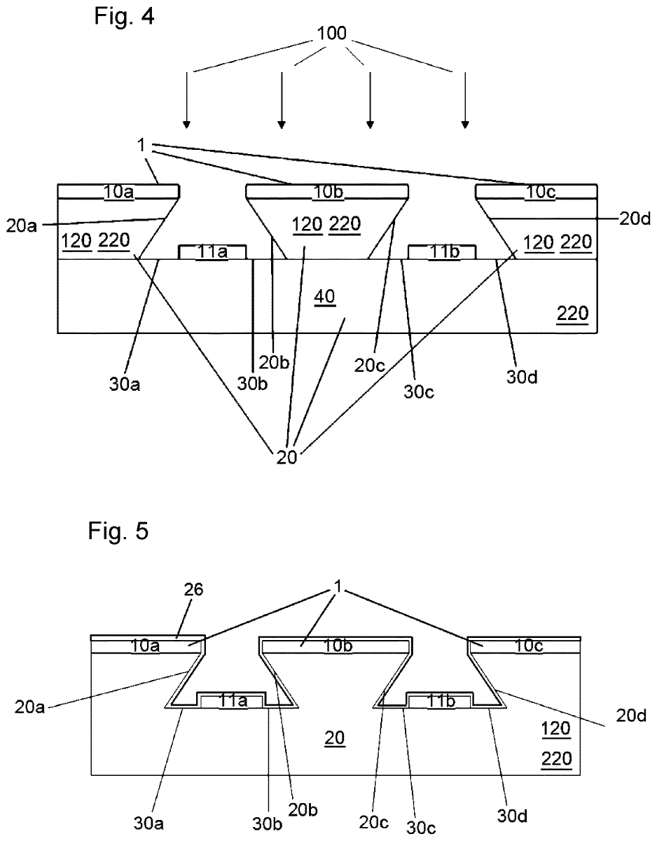

FIG. 3 schematically shows the definition according to the invention of the projection direction p 100 and of the undercut 20a according to the invention related thereto and of the associated shaded area 30a in the support structure 20 according to the invention. In the case outlined, the two subregions 120, 220 are identical and form the support structure 20. The shaded area 30a comprises the totality of all points P 1015 on the surface of the support structure 20, for which a half-line g 1016 emanating from point P 1015 and oriented opposite to the projection direction p 100, cuts through the support structure 20. The totality of the portions 1030 of all such half-lines g 1016 located inside the support structure 20 defines the subregion of the support structure 20 referred to as overhang 1020. The overhang 1020 defines a shaded region 1040—this comprises the totality of the connecting lines PP′ 1031 of the points P 1015 lying outside the support structure 20 to the entry point P′ of the associated half-line g 1016 into the support structure 20 located nearest to it opposite to the projection direction p 100.

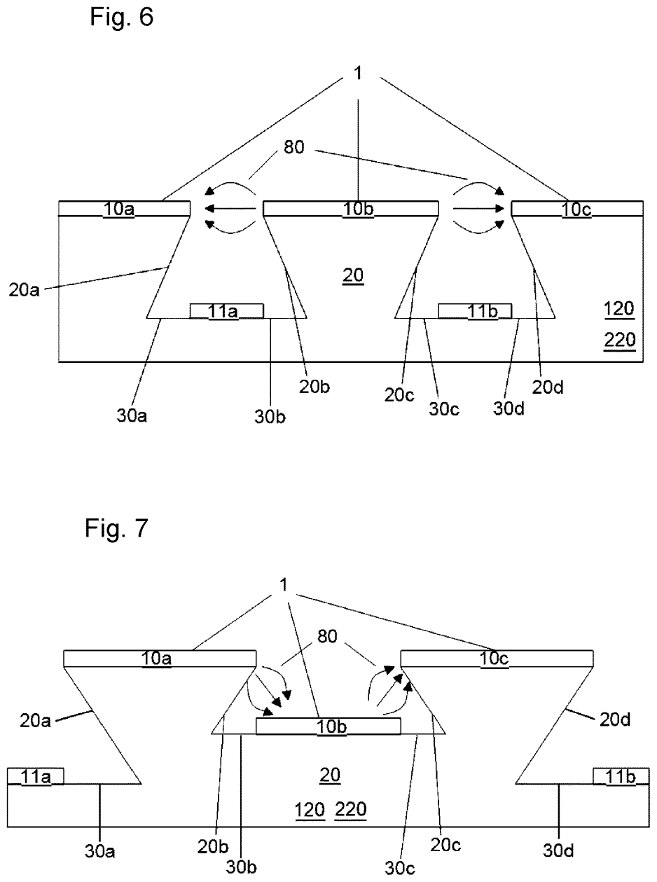

FIG. 4 shows an exemplary embodiment of the electrical line arrangement according to the invention in the form of a schematic cross-sectional drawing, in which the support structure 20 comprises a substrate 40. The first subregions 120 of the support structure are produced from an electrically insulating material by using a free-form microstructuring process. As the substrate 40, an electrically insulating carrier material is used, which is not produced in the same production process as the first subregions 120 of the support structure 20. In this exemplary embodiment, the electrically insulating second subregion 220 of the support structure 20 comprises both the substrate 40 and the first subregions 120 of the support structure 20, which are produced by using the free-form microstructuring process. The support structure 20 is coated—analogously to the illustration in FIG. 2—with respect to the projection direction 100 with at least one electrically conductive material. The coating forms—also analogously to FIG. 2—the electrically conductive structures 10a, 10b, 10c insulated from one another and the additional electrically conductive structures 11a, 11b. In contrast to the illustration according to FIG. 2, the additional electrically conductive structures 11a, 11b and the exposed areas 30a, 30b, 30c, 30d here, however, are on the surface of the substrate 40 and not (or not exclusively; not shown here) on the surface of the first subregion 120 of the support structure 20 produced by a free-form microstructuring process.

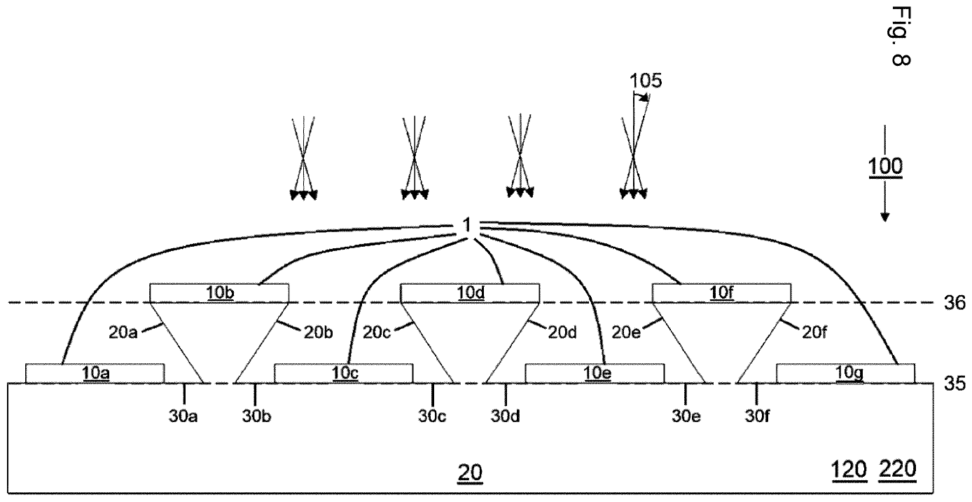

FIG. 5 shows a further exemplary embodiment of the electrical line arrangement according to the invention in the form of a schematic cross-sectional drawing, in which an isotropic coating with an inert protective material 26 is applied to the support structure 20, the electrically conductive structures 10a, 10b, 10c forming the electrical line structure 1 and to the additional electrically conductive structures 11a, 11b. The line arrangement sketched as an example in FIG. 5 can be produced in this case analogously to the procedure described in FIG. 1 and FIG. 2. In the embodiment illustrated in FIG. 5, the two subregions 120, 220 are identical and form the support structure 20. After production, the inert protective material 26 can be applied by an isotropic process in which the structure is coated on all sides. The inert protective material 26 can be designed, for example, to prevent oxidation of the metal regions 10a, 10b, 10c, 11a, 11b.

FIG. 6 schematically shows the cross-section of a further electrical line arrangement according to the invention, which can be produced with the present method. In the embodiment illustrated in FIG. 6, the two subregions 120, 220 are identical and form the support structure 20. The electrical line structure 1 according to FIG. 6 forms a coplanar line, which comprises the three electrically conductive structures 10a, 10b, 10c, which are electrically isolated from one another in all cross-sectional planes along the line structure 1, wherein here the two electrically conductive structures 10a, 10c can be at the same potential, for example in the case of a so-called “ground-signal-ground” configuration. In order not to admit any short circuits between the resulting electrically conductive structures 10a, 10b, 10c and the further electrically conductive structures 11a, 11b, here also during the directed coating of the surface of the support structure 20 along the projection direction 100, the slots introduced into the support structure 20 between the regions to be coated are provided with the undercuts 20a, 20b, 20c, 20d, which are designed to provide the exposed areas 30a, 30b, 30c, 30d intended for insulation purposes. The undercuts 20a, 20b, 20c, 20d in the support structure 20 in the present exemplary embodiment are designed to be sufficiently deep that the signal routing in the desired electrical line structure 1, which comprises the electrically conductive structures 10a, 10b, 10c, cannot be influenced by the electrically conductive structures 11a, 11b that inevitably still occur on the support structure 20. This is indicated in FIG. 6 with reference to field lines of an electric field 80, the course of which is not adversely affected by the further electrically conductive structures 11a, 11b, in particular due to a sufficient spacing. The additional electrically conductive structures 11a, 11b generated as a “by-product” in this exemplary embodiment can thus remain in their position on the surface of the support structure 20 (or alternatively on the surface of the substrate 40; not shown here) and therefore need not be removed.

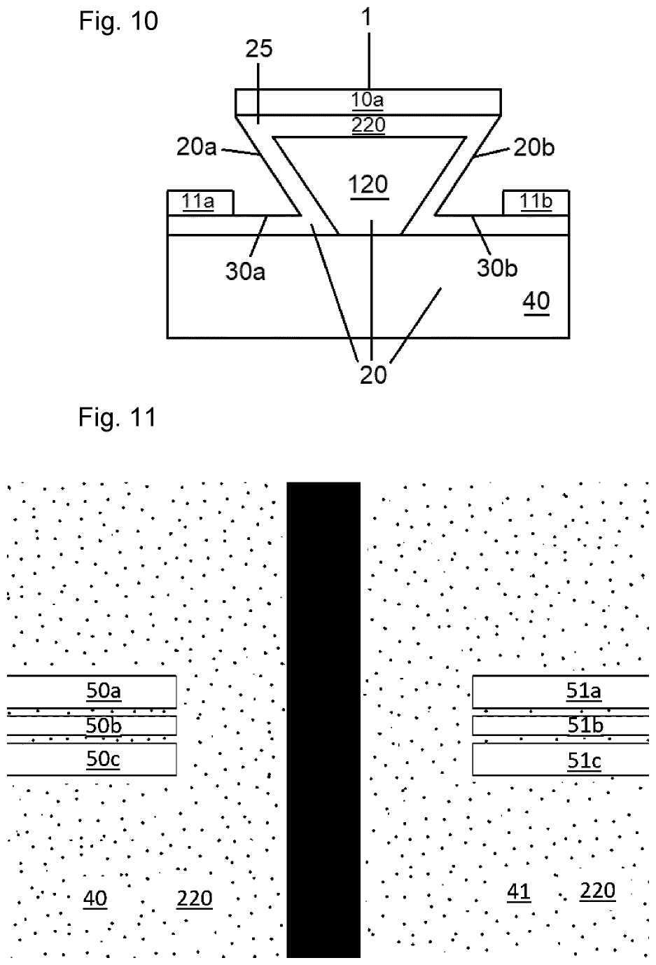

FIG. 7 schematically shows the cross-section of a further electrical line arrangement according to the invention, which can also be produced with the present method. In the embodiment illustrated in FIG. 7, the two subregions 120, 220 are identical and form the support structure 20. In this case, the electrical line structure 1 is designed in the form of an electrical line coupler. The electrical line structure 1 in the form of the electrical line coupler comprises the three electrically conductive structures 10a, 10b, 10c, wherein two of the electrically conductive structures 10a, 10c are electrically insulated from each other in all cross-sectional planes along the line structure 1 and are at different electrical potentials from each other. The distance between the two electrically conductive structures 10a, 10c is chosen such that a cross-coupling of the electric field 80 from one electrically conductive structure 10a to the other electrically conductive structure 10c (or vice versa) can be adjusted via the third electrically conductive structure 10b, which is located in an incision in the support structure 20, schematically illustrated in FIG. 7. A width of the third electrically conductive structure 10b is determined in this case by using the undercuts 20b, 20c inserted into the support structure 100, which are designed as shading structures with respect to the projection direction 20, and the exposed areas 30b, 30c defined by these shading structures. This embodiment is particularly advantageous in the case of strong cross-coupling, for which small distances between the two electrically conductive structures 10a, 10c are required that are more difficult to produce using planar lithography processes with limited lateral resolution. By using the third electrically conductive structure 10b, which can be produced by coating the electrically conductive material, the strength of the cross-coupling can be increased while maintaining a constant distance. Undesirable influencing of the electrical line structure 1 by the other electrically conductive structures 11a, 11b generated as a “by-product” on the two outer sides of the support structure 20 can be prevented by the additional undercuts 20a, 20d inserted in the support structure 20. These two undercuts 20a, 20d are deeper than the undercuts 20b, 20c in the exemplary embodiment according to FIG. 7, which is why the further electrically conductive structures 11a, 11b determined on the basis of the defined exposed areas 30a, 30d are a greater distance from the electrically conductive structures 10a, 10c of the electrical line structure 1. Thus, cross-coupling of the electric field 80 from the electrical line structure 1 to the other electrically conductive structures 11a, 11b can be prevented.

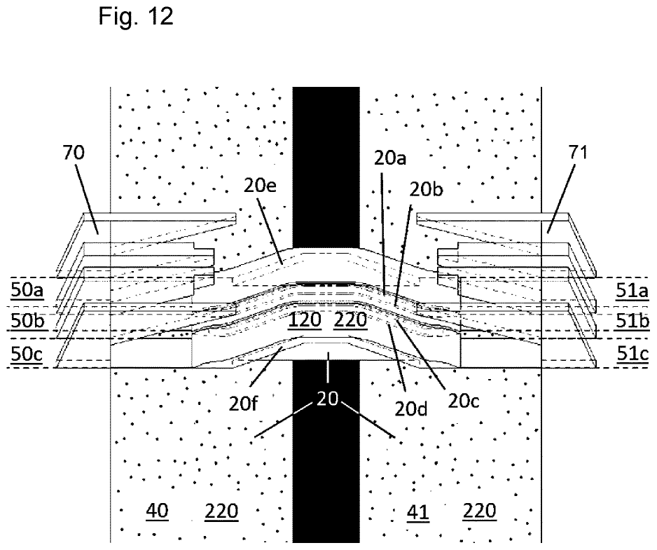

FIG. 8 schematically shows the cross-section of a further electrical line arrangement according to the invention, which can also be produced with the present method. In the embodiment illustrated in FIG. 8, the two subregions 120, 220 are identical and form the support structure 20. In this case, the electrical line structure 1 is designed in the form of an electrical interdigital capacitance. The electrical line structure 1 in the form of the electrical interdigital capacitance comprises by way of example the seven electrically conductive structures 10a, 10b, 10c, 10d, 10e, 10f, 10g, which are arranged substantially alternately in two different planes 35, 36 running parallel to each other and wherein these can be at different potentials. For example, the four electrically conductive structures 10a, 10c, 10e, 10g are located in a common first plane 35 defined by recesses in the support structure 20, while the remaining three electrically conductive structures 10b, 10d, 10f are located in a second plane 36 defined by webs between the recesses. To produce the electrical line arrangement 1, undercuts 20a, 20b, 20c, 20d, 20e, 20f are introduced into the support structure 20 with respect to the projection direction 100, which by using the exposed areas 30a, 30b, 30c, 30d, 30e, 30f ensure electrical insulation of the electrically conductive structures 10a, 10b, 10c, 10d, 10e, 10f, 10g applied on the two different planes 35, 36. In the case outlined, the flow of evaporation beams emanating from the evaporation source exhibits a divergence 105 around the defined projection direction 100 at the location of the support structure 20 to be coated, which means that the width of the strip-like electrically conductive structures 10a, 10c, 10e, 10g generated in the first plane 35 is increased so that in a projection along the projection direction 100, they overlap with the electrically conductive structures 10b, 10d, 10f located in the second plane 36. This can contribute in particular to increasing the electrical capacitance between the structures on the two planes 35, 36. The electrically conductive structures 10a, 10c, 10e, 10g and/or 10b, 10d, 10f located in a common plane 35, 36 can be electrically connected to one another in a further cross-sectional plane of the electrical line structure 1 and thus form a common electrical supply line.

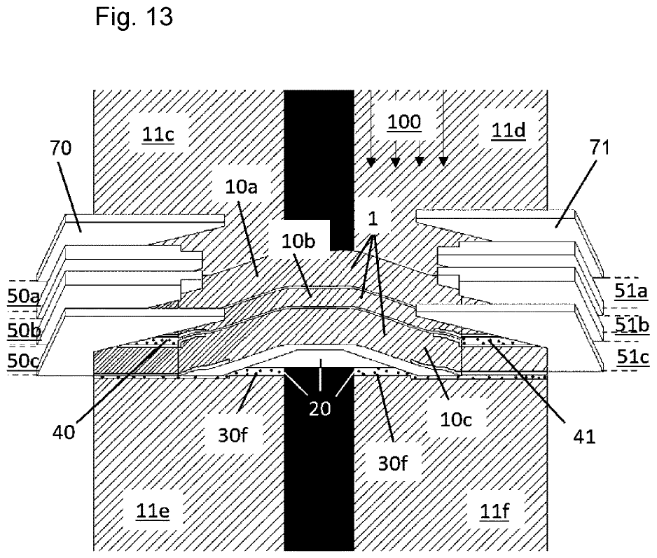

FIG. 9 shows an exemplary embodiment of the electrical line arrangement according to the invention in the form of a schematic cross-sectional drawing, in which the support structure 20 comprises a substrate 40, which comprises an upper electrically conductive subregion 320 and a lower electrically insulating second subregion 220. The first subregions 120 of the support structure 20 are produced from an electrically insulating material by using a free-form microstructuring process. In this case, the electrically insulating second subregion 220 of the support structure 20 consists of a plurality of elements and comprises both the lower second subregion 220 of the substrate 40 and all first subregions 120 of the support structure 20, which are produced by using the free-form microstructuring process. The support structure 20 is coated—analogously to the illustration in FIG. 4—with respect to the projection direction 100 with the at least one electrically conductive material. The coating forms—also analogously to FIG. 4—the electrically conductive structures 10a, 10b, 10c insulated from one another and the additional electrically conductive structures 11a, 11b. In contrast to the illustration according to FIG. 4, however, further first subregions 120 of the support structure 20 can be produced on the substrate 40 by using a free-form microstructuring process, in such a way that during the coating, a via 15 is generated between at least one of the electrically conductive structures 10a, 10c and at least one further conductive structure present in the arrangement by using the electrically conductive subregion 320 of the substrate 40. This can be achieved, for example, via corresponding ramp structures in the first subregion 120 produced by using the free-form microstructuring process.

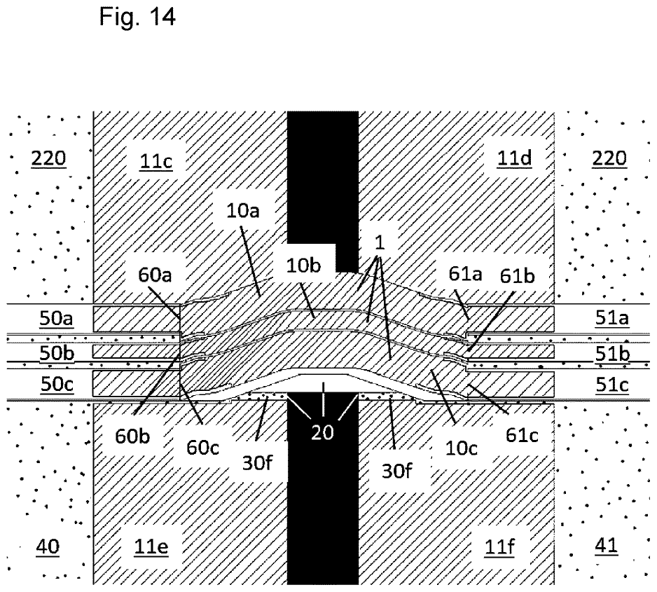

FIG. 10 shows an exemplary embodiment of the electrical line arrangement according to the invention in the form of a schematic cross-sectional drawing, wherein the support structure 20 comprises an electrically conductive or insulating substrate 40, a first subregion 120 produced by a free-form microstructuring process applied thereon, and an insulating coating 25 substantially homogeneously surrounding the substrate 40 and the first subregion 120, wherein the insulating coating 25 forms the insulating second subregion 220 of the support structure 20 and is applied, for example, by an isotropic coating process. In this case, the two subregions 120, 220 are therefore disjoint, i.e. non-intersecting. The support structure 20 shown can then—analogously to FIG. 2—be coated with at least one electrically conductive material along the projection direction 100 in order to form the electrical line structure 1 consisting of the electrically conductive structure 10a. In contrast to the illustration according to FIG. 2, the additional electrically conductive structures 11a, 11b and the exposed areas 30a, 30b here are on the surface of the insulating coating 25, however, and not on the surface of the first subregion 120 of the support structure 20 produced by a free-form microstructuring process.

In a particular embodiment (not shown here), the electrically conductive structures 10a, 10b, 10c, etc. and the additional electrically conductive structures 11a, 11b, etc., of the electrical line structures 1 schematically illustrated in FIGS. 2, 4, 5, 6, 7, 8, 9 and 10 along the direction of propagation of the electromagnetic signal, which in the cases outlined runs substantially perpendicular to the respective drawing plane, can vary in cross-section and/or follow a non-planar trajectory. This non-planar trajectory may be predetermined by a corresponding non-planar shape of the support structure 20, wherein in particular the use according to the invention of a free-form microstructuring process opens up new options for embodiments. In a further embodiment, the substrate 40 contained in the support structure 20 may also have a non-planar shape, which defines or significantly influences the trajectory of the line profile. In addition, for example, a cross-section of the electrical line structure 1 can vary along the direction of propagation of the electromagnetic wave. This allows a line impedance to be locally matched according to the varying cross-section, or line transitions 60a, 61a matched at both ends to be generated in electrical connecting elements. Alternatively, certain components defined by the respective shape of the electrical line structure 1, in particular with capacitive, resistive or inductive effect, can be generated.

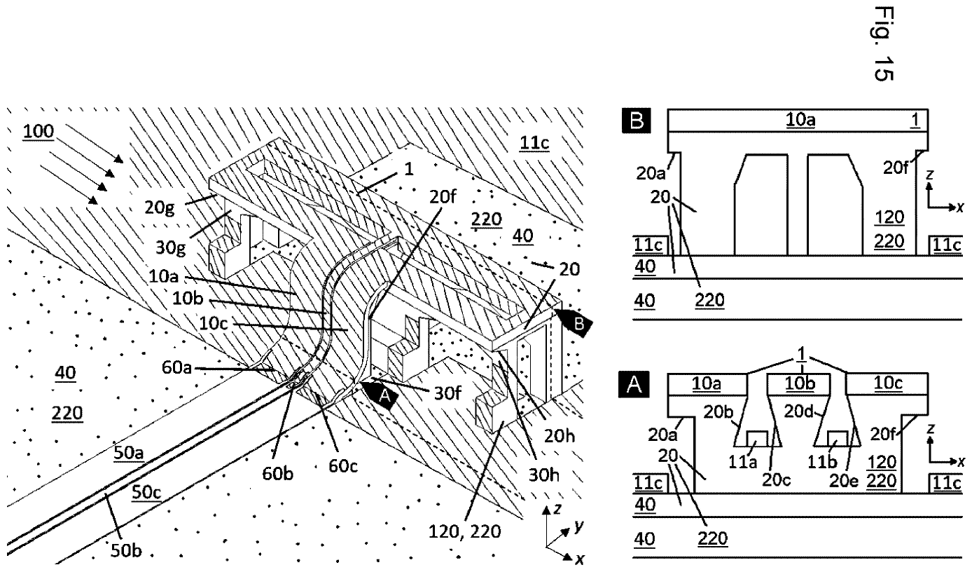

FIGS. 11 to 14 schematically show a process sequence for producing an additional electrical line arrangement according to the invention, which is embodied as a non-planar electrical connecting element between the two separate substrates 40, 41, according to the manufacturing method described herein using additional shading structures 70, 71. FIG. 11 schematically shows an initial situation in which the two insulating substrates 40, 41 are approximately aligned facing each other. Each of the two substrates 40, 41 comprises already existing line structures 50a, 50b, 50c; 51a, 51b, 51c, sketched here by way of example as conventional coplanar lines, wherein the line structures were previously produced by using the method described herein and/or by using conventional manufacturing methods. The coplanar lines each comprise three electrically conductive structures, which are electrically insulated from one another in all cross-sectional planes along the line structure, wherein the two already existing electrically conductive structures 50a, 50c; 51a, 51c are each at the same potential.

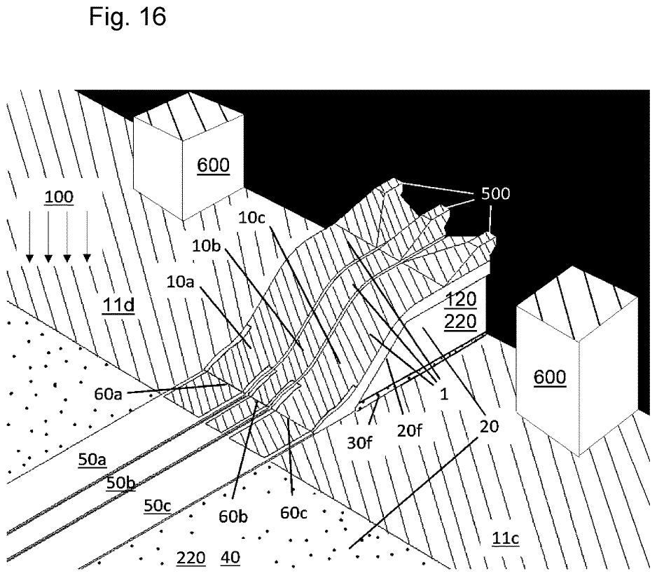

FIG. 12 schematically shows a first method step according to which the production of the first subregion 120 of the support structure 20 is carried out by using a free-form microstructuring process from an electrically insulating material. In this embodiment, the first subregion 120 of the support structure 20 forms a connection between the conventional coplanar lines and in doing so bridges at least one possibly existing gap between the two substrates 40, 41.

By using a free-form microstructuring process according to the invention, it is in particular possible in the structures shown in FIGS. 11 to 14 to adapt the geometry of the first subregion 120 of the support structure 20 to the positioning of the two substrates 40, 41, which is not always precisely controllable. Thus, it is in particular possible to mount these substrates 40, 41 firstly with an inexpensive method with comparatively large positioning tolerances, and then to record the exact position of the ends of the existing line structures 50a, 50b, 50c; 51a, 51b, 51c to be connected, and on the basis of this information to design the first subregion 120 of the support structure 20 to be produced by the free-form microstructuring process. The first subregion 120 adapted to the position of the line ends to be connected can then be implemented with high precision on the substrates 40, 41, which allows a precisely defined, for example broadband and/or low-loss electrical line transition 60a, 60b, 60c; 61a, 61b, 61c between the existing line structures 50a, 50b, 50c; 51a, 51b, 51c to be achieved. For precise recording of the position of the ends of the existing line structures 50a, 50b, 50c; 51a, 51b, 51c to be connected and for the precise alignment of the first subregion 120 adapted to the position of the line ends to be connected on the substrates 40, 41, the device used for the implementation of the free-form microstructuring process may be equipped with additional image acquisition functions, which allow, for example, markers or structural elements on the substrates 40, 41 to be precisely detected. In the case of two-photon lithography methods, such functions can be based, for example, on camera-based 2D or 3D imaging methods or on scanning methods, for example, according to the principle of confocal microscopy. The precision with which structures can be detected on the substrates 40, 41 and corresponding first subregions 120 can be placed on these substrates 40, 41 is preferably better than 100 μm, particularly preferably better than 10 μm, in particular preferably better than 1 μm, 300 nm, or 100 nm.

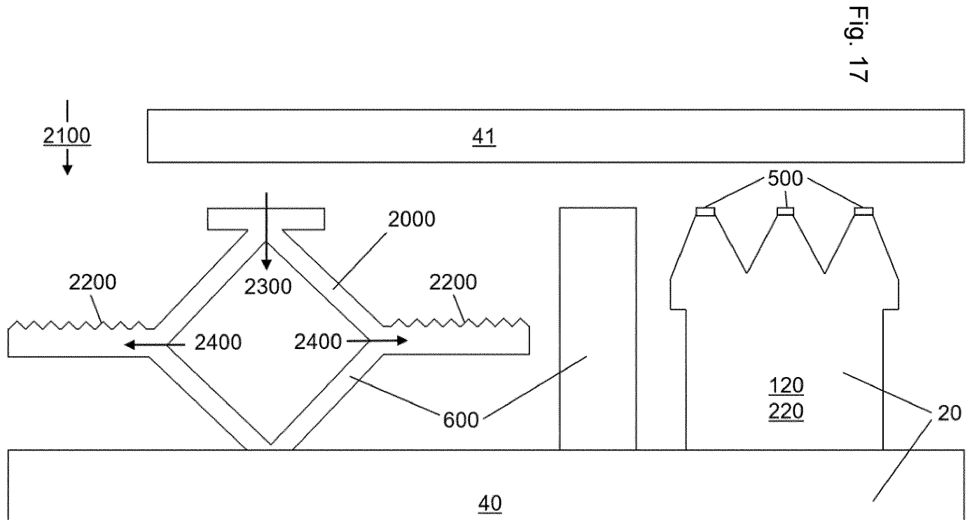

In order to prevent short circuits being generated between the resulting electrically conductive structures 10a, 10b, 10c; 11a, 11b, 11c, 11d, 11e, 11f during the coating of the support structure 20 with the electrically conductive material along the projection direction 100 shown in FIG. 13, corresponding exposed areas 30a, 30b, 30c, 30d, 30e, 30f are generated between these structures by using suitable undercuts 20a, 20b, 20c, 20d, 20e, 20f. The undercuts 20a, 20b, 20c, 20d, 20e, 20f are designed sufficiently deep in the cross-section of the electrical line structure 1 that—analogous to the illustration in FIG. 6—the electrically conductive structures 10a, 10b, 10c are not affected, or only insignificantly or locally in a desired manner, by the electrically conductive structures 11a, 11b, 11c, 11d, 11e, 11f generated as a “by-product”.

In order to further prevent the coating from also causing the already existing electrically conductive structures 50a, 50b, 50c; 51a, 51b, 51c to be short-circuited to one another, additional shading structures 70, 71 in the form of a plurality of projecting arms are used. The additional shading structures 70, 71 are aligned to the transitions between the already existing electrically conductive structures 50a, 50b, 50c; 51a, 51b, 51c and the electrical line structure 1 in such a way that during the coating under the defined projection direction 100 no connection between the already existing electrically conductive structures 50a, 50b, 50c; 51a, 51b, 51c can be produced in any of the cross-sectional planes along the line structure 1.

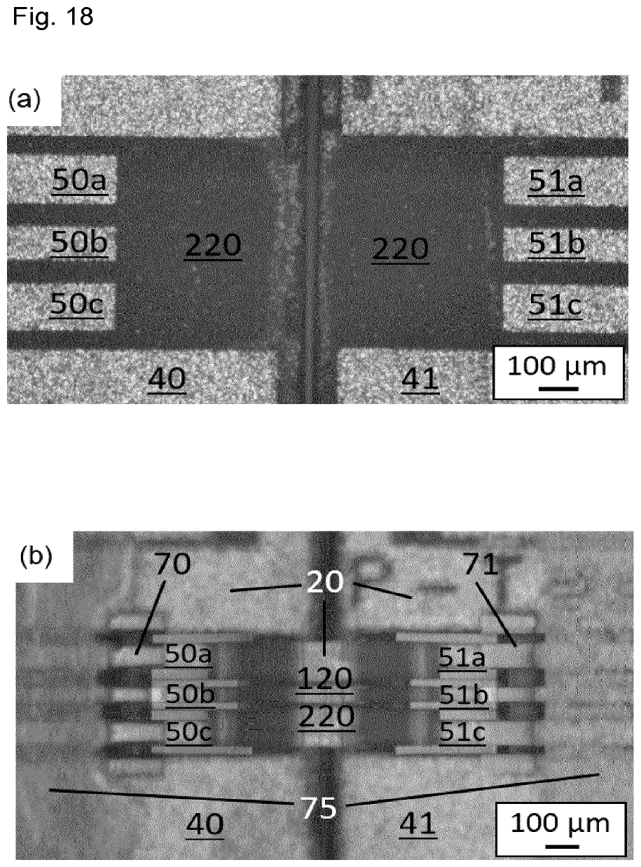

The additional shading structures 70, 71 can preferably be produced with the same free-form microstructuring process as in method step a) together with the first subregion 120 of the support structure 20. Due to the coating in the projection direction 100 in method step b), as shown schematically in FIGS. 13 and 14, first electrical line transitions 60a, 60b, 60c are formed between the already existing electrically conductive structures 50a, 50b, 50c on the first substrate 40 and the electrically conductive structures 10a, 10b, 10c of the electrical line structure 1, and additional electrical line transitions 61a, 61b, 61c are formed between the additional already existing electrically conductive structures 51a, 51b, 51c on the additional substrate 41 and the electrically conductive structures 10a, 10b, 10c of the electrical line structure 1. The additional electrically conductive structures 11a, 11b, 11c, 11d, 11e, 11f that are also formed on the substrates 40, 41 of the support structure 20 as a “by-product” do not influence the electrical line structure 1, or only insignificantly or in a precisely known manner that can be taken into account in the execution.

FIG. 14 schematically shows the completed electrical line arrangement after the additional shading structures 70, 71 were removed beforehand. The additional shading structures 70, 71 can preferably be removed by simply peeling them off using a pair of tweezers or a lift-off process already mentioned above. In addition to the additional shading structures 70, 71 described above, the two substrates 40, 41 may at least be provided with corresponding temporary or permanent protective layers 75 (not shown here), which prevents unwanted coating of the substrate surfaces or corresponding subregions during the coating process in method step b). These protective layers can be produced, for example, by suitable lithography, printing or dispensing methods and removed again with suitable solvents after carrying out method step b).

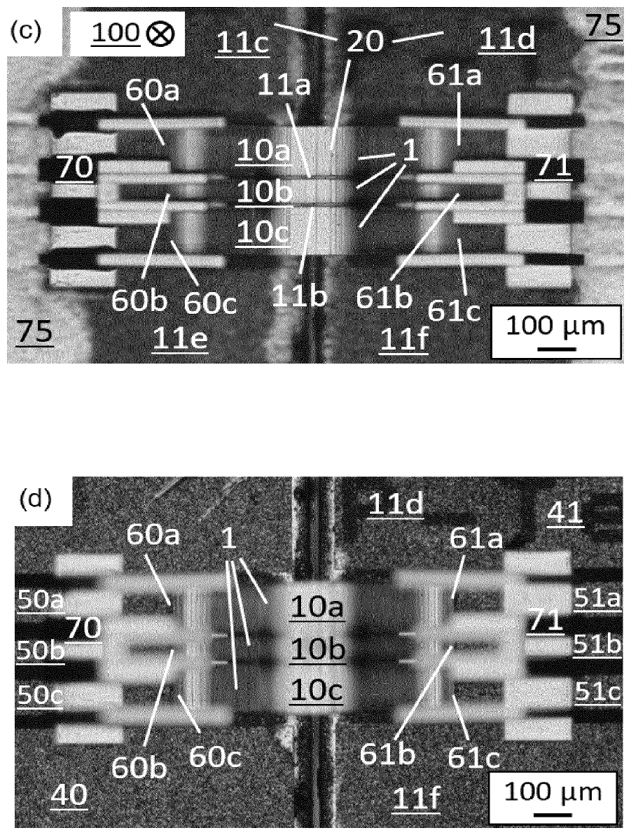

FIG. 15 schematically shows another exemplary embodiment of the electrical line arrangement according to the invention, which is embodied here in the form of a non-planar dipole antenna. The electrical line arrangement comprises the insulating substrate 40, which comprises a conventionally manufactured coplanar line consisting of three existing electrically conductive structures 50a, 50b, 50c, wherein two of the existing electrically conductive structures 50a, 50c can be at the same electrical potential. In this embodiment, the electrical line structure 1 initially comprises three individual electrically conductive structures 10a, 10b, 10c electrically insulated from one another within a cross-sectional plane, which are varied in their respective geometry in a defined manner along the line structure 1 and in particular are also electrically connected within at least one further cross-sectional plane of the electrical line structure 1.

Method step a) comprises the production of the first subregion 120 of the support structure 20 generated by a free-form microstructuring process from an electrically insulating material according to FIG. 15. In order to be able to coat surfaces at an angle of 90° to the surface of the substrate 40, the projection direction 100 is set here to an angle of, for example, 45° to the surface of the substrate 40. Both the side walls of the slots between the structures to be coated and also the outer walls of the first subregion 120 of the support structure 20 have undercuts 20a, 20b, 20c, 20d, 20e, 20f in the region of the ramp structure shown in FIG. 15, which are designed to produce the exposed areas 30a, 30b, 30c, 30d, 30e, 30f along the ramp structure. The undercuts 20a, 20b, 20c, 20d, 20e, 20f are designed sufficiently deep that the electrical line structure 1, which comprises the electrically conductive structures 10a, 10b, 10c,—analogous to the illustration in FIG. 6—cannot be affected by the electrically conductive structures 11a, 11b, 11c generated as a “by-product”, or only insignificantly or in a known manner that must be taken into account during the execution. The further undercuts 20g, 20h introduced in the feet and flanks of the first subregion 120 of the support structure 20 generated by a free-form microstructuring process are designed to produce the exposed areas 30g, 30h, which provide the electrical insulation of the electrically conductive structures 10a, 10b, 10c comprised by the electrical line structure 1 from the substrate 40 and/or the electrically conductive structures 11c formed on the substrate 40 as a “by-product”.

By using the coating of the support structure 20 with the electrically conductive material along the projection direction 100, the electrical line transitions 60a, 60b, 60c are formed between the already existing electrically conductive structures 50a, 50b, 50c on the substrate 40 and the electrically conductive structures 10a, 10b, 10c of the electrical line structure 1. The electrically conductive structures 10a, 10b, 10c insulated from one another within an exemplary sketched cross-sectional plane A (section in (x, z) plane) are routed upwards via the ramp structure, wherein within at least one further exemplary sketched cross-sectional plane B (section in (x, z) plane) the two outer electrically conductive structures 10a, 10c are combined centrally there with the middle electrically conductive structure 10b configured as a signal conductor, thus forming a dipole antenna. If the design is correct, an efficient matching of the line impedance of the electrical line structure 1 to the wave resistance of free space and thus a radiation of the dipole antenna thereby generated can be achieved, without the possibly increased permittivity of the substrate 40 causing a problem.

Also in this exemplary embodiment, additional shading structures 70 (not shown here), analogous to the arrangements shown in FIGS. 12 and 13, can be used to enable an electrical connection of the electrically conductive structures 10a, 10b, 10c to the already existing electrically conductive structures 50a, 50b, 50c without producing a short circuit between the electrically conductive structures 10a, 10b, 10c or the already existing electrically conductive structures 50a, 50b, 50c to the substrate 40 and/or to the electrically conductive structures 11a, 11b, 11c formed on the substrate 40 as a “by-product”.

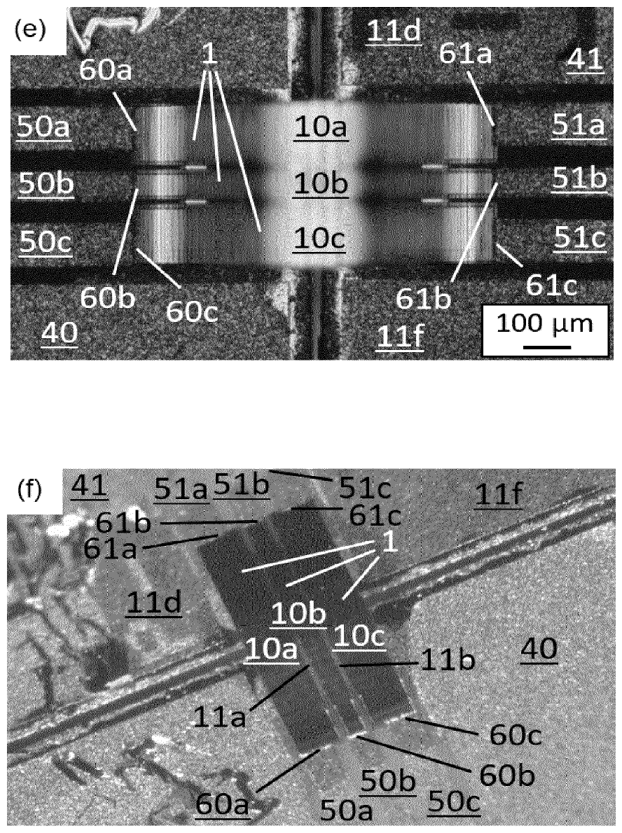

FIG. 16 schematically shows a further exemplary embodiment of the electrical line arrangement according to the invention, which is here embodied in the form of an electrical probe tip that can be particularly suitable for contacting RF circuits. The electrical line arrangement schematically illustrated in FIG. 16 can preferably be produced analogously to the method steps according to FIGS. 11 to 14 and the electrical line arrangement schematically illustrated in FIG. 15. For further details reference is therefore made to the description of the FIGS. 11 to 15.

In FIG. 16, the projection direction 100 is set to an angle of 90° to the surface of the insulating substrate 40. By using the coating of the support structure 20 with the electrically conductive material along the projection direction 100, the electrical line transitions 60a, 60b, 60c are formed between the already existing electrically conductive structures 50a, 50b, 50c on the substrate 40 and the electrically conductive structures 10a, 10b, 10c of the electrical line structure 1. The electrically conductive structures 10a, 10b, 10c, which remain insulated in all cross-sectional planes along the line structure 1, are here also routed upwards via the ramp structure schematically shown in FIG. 16 and converge there at a specified distance in order to form three contact elements 500. The production of the first subregion 120 according to the invention with the aid of a free-form microstructuring process again allows a very precise alignment to structures already present on the substrate 40, see explanations for FIGS. 11 to 15, as well as a very dimensionally accurate manufacture of the electrical line structures 1 with flexibly adjustable electrical parameters, such as the impedance of the line arrangement and of the transition to a further test substrate (not shown) defined by the contact elements 500.

The structure shown in FIG. 16 further comprises contact elements 500, which were generated by an appropriate shaping of the support structure to be coated 20 and with which a geometrically precise contacting of corresponding contact surfaces on a chip or a flat substrate is possible. In the embodiment sketched in FIG. 16, the contact elements 500 are based on structural elements protruding in a direction perpendicular to the coated surface, which in the case sketched take the form of pyramid frustums. Other geometrical configurations of the contact elements 500 are conceivable.

Also in this exemplary embodiment, as shown in FIGS. 12 and 13, additional shading structures 70 (not shown) can be used to enable an electrical connection of the electrically conductive structures 10a, 10b, 10c to the already existing electrically conductive structures 50a, 50b, 50c in all cross-sectional planes along the line structure 1, without producing a short circuit between the electrically conductive structures 10a, 10b, 10c or the already existing electrically conductive structures 50a, 50b, 50c to the substrate 40 and/or to the electrically conductive structures 11a, 11b, 11c, 11d formed on the substrate 40 as a “by-product”.

The support structure 20 in this case may be designed in particular such that the three contact elements 500—as indicated in FIG. 16—protrude to the right beyond the edge of the substrate 40 and thus remain visible for contacting even in a rotated arrangement of the electrical line structure 1, where the contact elements 500 point downwards and a camera image taken from above is used for the positioning. The manifold options for designing the first subregion 120 of the support structure 20 produced by a free-form microstructuring process also allow mechanical protective structures 600 to be generated by using the free-form microstructuring process according to method step a) or by using a different free-form microstructuring process, which prevent unwanted mechanical damage to the electrical probe tip, for example, due to a collision or misaligned placement onto a test substrate underneath. The mechanical protective structures 600 can be designed, as shown in FIG. 16, as solid protective structures 600 which prevent an unwanted approach of the electric probe tip to an object that would damage the probe tip. As an alternative or in addition, the protective structures 600 can be designed such that an approach of the electrical probe tip or the contact elements 500 to an object that would damage them, for example a substrate 41, will lead to a demonstrable elastic or partially elastic deformation of the protective structure 600 or a part thereof, see FIG. 17. Dedicated monitor structures 2000 with indicator structures 2200 can be used for this purpose, which can be used to convert an approach 2300 of the electrical probe tip to the potentially damaging object substantially along a viewing direction 2100 into a deformation 2400 of the monitor structure 2000 laterally to the viewing direction 2100 and thus visually detectable. In a preferred embodiment, the monitor structures 2000 or parts thereof can be produced jointly with the first subregion 120 of the support structure 20 by a free-form microstructuring process.

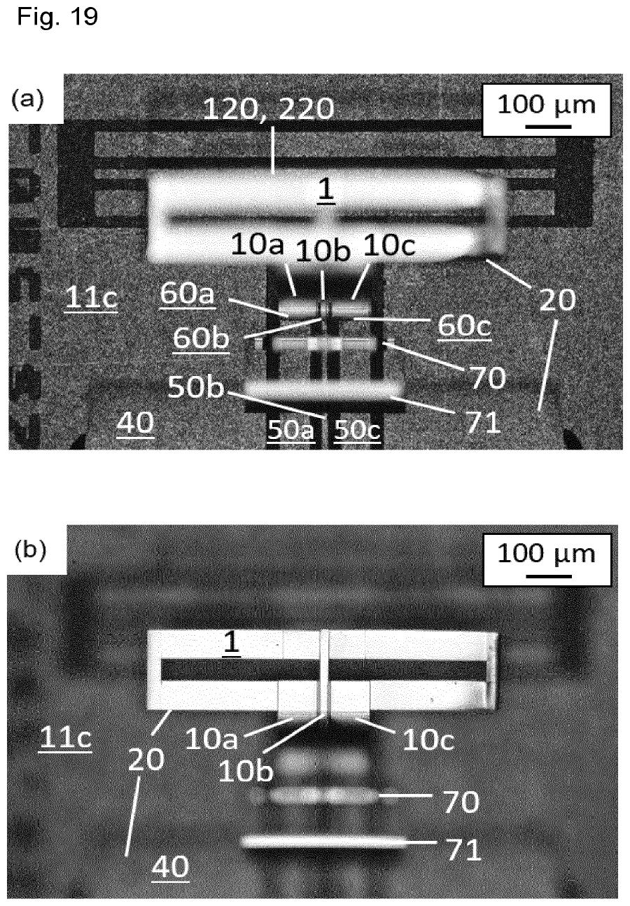

In FIG. 18, a further exemplary embodiment of the method sequence according to FIGS. 11 to 14 for producing a further electrical line arrangement according to the invention is shown in the form of microscope images. For further details, reference is made to the above description of FIGS. 11 to 14.

FIG. 18(a) shows the additional electrical line arrangement according to the invention, which comprises the two substrates 40, 41, each having an already existing electrical line structure which are provided with the already existing electrically conductive structures 50a, 50b, 50c; 51a, 51b, 51c, wherein two of the two already existing electrically conductive structures 50a, 50c; 51a, 51c are each at the same potential. The substrates 40, 41 comprise—analogous to the structure sketched in FIG. 9—in each case in a second subregion 220, an insulating support body made of aluminum oxide (Al₂O₃) with a layer thickness of 625 μm, and a conductive region 320 which was produced on the insulating support body by using a gold layer with a layer thickness of 3 μm. The already existing electrically conductive structures 50a, 50b, 50c; 51a, 51b, 51c were produced by structuring this gold layer, for example by using a conventional lithography process or a laser ablation process.

The existing electrically conductive structures 50a, 50b, 50c; 51a, 51b, 51c will subsequently be connected in an electrically conductive manner to their respective counterpart. For this purpose, the first subregion 120 of the support structure 20 shown in FIG. 18(b) is produced from an insulating material by using a two-photon lithography process. In this example, the electrically insulating second subregion 220 of the support structure 20 comprises both the lower second subregion 220 of the substrates 40, 41 as well as the first subregions 120 of the support structure 20, which are produced by using the free-form microstructuring process. Due to restrictions on the write-field size, the electrical line arrangement was divided into multiple sections and manufactured in multiple steps.

In order to avoid producing short circuits between the resulting electrically conductive structures 10a, 10b, 10c; 11a, 11b, 11c, 11d, 11e, 11f from the coating of the support structure by using the electrically conductive material in FIG. 18(c) using a PVD process along the projection direction 100 at an angle of 90° to the surface of the substrates 40, 41, the first subregion 120 of the support structure 20 has slots, in the side walls of which the undercuts 20a, 20b, 20c, 20d, 20e, 20f are formed, which are designed for producing the exposed areas 30a, 30b, 30c, 30d, 30e, 30f. The undercuts 20a, 20b, 20c, 20d, 20e, 20f are designed sufficiently deep that the electrical line structure 1, which comprises the electrically conductive structures 10a, 10b, 10c—analogous to the illustration in FIG. 6—is either not affected by the electrically conductive structures 11a, 11b, 11c, 11d, 11e, 11f generated as a “by-product”, or only insignificantly or in a known manner that must be taken into account during the execution.

Due to the coating in the projection direction 100, on the one hand first electrical line transitions 60a, 60b, 60c are formed between the already existing electrically conductive structures 50a, 50b, 50c on the left-hand substrate 40 shown in FIG. 18(b) and the electrically conductive structures 10a, 10b, 10c generated according to the invention of the electrical line structure 1, and on the other hand additional electrical line transitions 61a, 61b, 61c are formed between the additional existing electrically conductive structures 51a, 51b, 51c on the right-hand substrate 41 shown in FIG. 18(b) and the electrically conductive structures 10a, 10b, 10c of the electrical line structure 1. The coating thus produced on the support structure 20 has a total layer thickness of approximately 600 nm along the projection direction 100, which largely comprises a copper layer due to the high electrical conductivity. A thin layer of titanium serves as an adhesion promoter between the support structure 20 and the copper layer; a thin layer of gold is also applied as an outer layer for passivation against the environment. To prevent gold from diffusing from the gold layer into the copper layer, a further thin titanium layer can be inserted between the copper layer and the gold layer.

However, in order to prevent the existing electrically conductive structures 50a, 50b, 50c; 51a, 51b, 51c from also being short-circuited to themselves and to the respective adjacent substrate 40, 41, additional shading structures 70, 71 in the form of a plurality of protruding arms are used, which were prepared in advance preferably by using the same two-photon lithography process as the first subregion 120 of the support structure 20. The additional shading structures 70, 71 are aligned to the electrical line transitions 60a, 60b, 60c; 61a, 61b, 61c between the already existing electrically conductive structures 50a, 50b, 50c; 51a, 51b, 51c and the electrical line structure 1, in such a way that during the coating under the defined projection direction 100 no electrically conductive connection can arise between the already existing electrically conductive structures 50a, 50b, 50c; 51a, 51b, 51c or to the substrate 40, 41. The electrically conductive structures 11a, 11b, 11c, 11d, 11e, 11f formed as a “by-product”, are also electrically insulated. For this purpose, the effect of the shadow cast by the additional shading structures 70, 71 on the respective electrical line transitions 60a, 60b, 60c; 61a, 61b, 61c along the projection direction 100 is exploited. In this way, the three-dimensional electrical connecting element shown in FIG. 18 can be generated between the coplanar lines already present on the two substrates 40, 41, wherein the individual electrically conductive structures 10a, 10b, 10c remain electrically insulated from one another in all cross-sectional planes along the line structure 1.

The additional shading structures 70, 71 in the embodiment according to FIG. 18 are only designed for protecting the immediate environment of the electrical line transitions 60a, 60b, 60c; 61a, 61b, 61c due to the limited write-field size of the printing process, which is why a protective layer 75 of PMMA (polymethyl methacrylate) covers the already existing electrically conductive structures 50a, 50b, 50c; 51a, 51b, 51c over the remaining surface of the substrates 40, 41. The protective layer 75, which in the present exemplary embodiment was applied by using an inkjet printing process, is identifiable in FIG. 18(b) to the left of the additional shading structure 70 on the left-hand substrate 40 and to the right of the shading structure 71 on the right-hand substrate 41. In principle, further methods are conceivable that allow a large-area covering of the substrates 40, 41 with sufficient precision, for example lithographic processes, dispensing processes, or a simple covering with an adhesive film. The protective layer is further covered by using a metal layer in the course of the coating according to FIG. 18(c). By dissolving the PMMA layer with PGMEA (propylene glycol monomethyl acetate), the metal layer can be detached from the surfaces previously covered with the PMMA layer in a lift-off process, so that—as can be seen in FIG. 18(d)—the already existing electrically conductive structures 50a, 50b, 50c; 51a, 51b, 51c remain electrically insulated.

In principle, as already explained above, it may be conceivable and desirable to carry out the entire covering of the substrates 40, 41 with the same free-form microstructuring process which is also used for producing the first subregion 120 of the support structure 20 and the additional shading structures 70, 71, provided that the selected free-form microstructuring process allows this. Due to write-field limitations of the two-photon lithography process used here, the complete coverage of the substrates 40, 41 would take too long in practice due to the large surface area of the substrates 40, 41, which is why the printing and lift-off process described herein was used instead. The electrically conductive structures 11c, 11d, 11e, 11f formed as a “by-product” usually remain on the substrates 40, 41 without affecting the line structure 1, but can preferably—as revealed by a comparison of FIGS. 18(c) and 18(d)—be removed by peeling off using tweezers.

FIGS. 18(e) and 18(f) schematically show the completed electrical line arrangement after the additional shading structures 70, 71 were removed beforehand. The shadows generated on the support structure 20 using the additional shading structures 70, 71 during the coating are clearly visible in FIG. 18(e) in the form of darkened areas at the electrical line transitions 60a, 60b, 60c; 61a, 61b, 61c.

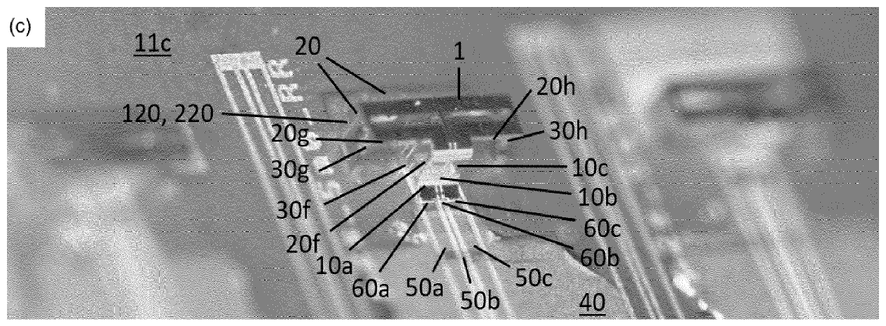

FIG. 19 shows, in the form of microscope images, a further exemplary embodiment of the electrical line arrangement according to the invention according to FIG. 15 as a non-planar dipole antenna. For further details reference is made to the description of FIG. 15.

FIG. 19 shows the electrical line arrangement comprising the substrate 40, which contains a conventionally manufactured coplanar line consisting of three existing electrically conductive structures 50a, 50b, 50c, wherein two of the existing electrically conductive structures 50a, 50c can be at the same electrical potential. The substrate 40 comprises—analogous to the structure sketched in FIG. 9—in each case in a second subregion 220, an insulating support body made of aluminum oxide (Al₂O₃) with a layer thickness of 625 μm, and a conductive region 320 which was produced on the insulating support body by using a gold layer with a layer thickness of 3 μm. The already existing electrically conductive structures 50a, 50b, 50c were produced by structuring this gold layer, for example by using a conventional lithography process or a laser ablation process. To produce the non-planar dipole antenna, which is a fixed distance from the substrate 40, here also the first subregion 120 of the carrier structure 20 was produced by using a two-photon lithography process and then coated with the electrically conductive material by using a PVD process. Due to restrictions on the write-field size, the electrical line arrangement was divided into multiple sections and manufactured in multiple steps. Since the support structure 20 in this exemplary embodiment also has surfaces at an angle of 90° to the surface of the substrate 40, in order to produce the desired distance of the non-planar dipole antenna from the substrate 40, a coating at this angle is not practical here. Therefore, the coating was applied with respect to a projection direction 100 according to FIG. 15, which has an angle of, for example, 45° to the surface of the substrate 40. The side walls of the slits introduced into the support structure 20 between the surfaces to be coated are provided—analogous to the exemplary embodiment according to FIG. 18—with undercuts 20a, 20b, 20c, 20d. The undercuts 20a, 20b, 20c, 20d are also designed here sufficiently deep that the electrical line structure 1, which comprises the electrically conductive structures 10a, 10b, 10c—analogous to the illustration in FIG. 6—cannot be affected by the electrically conductive structures 11a, 11b, 11c generated as a “by-product”, or only insignificantly or in a known manner that must be taken into account during the execution. The coating on the support structure 20, which is implemented for the most part as a copper layer or from a suitable sequence of different materials, here also has a total layer thickness of about 600 nm along the projection direction 100. A thin titanium layer serves as an adhesion promoter between the support structure 20 and the copper layer; for passivation relative to the environment, a thin gold layer is applied as an outer layer, wherein here also another thin titanium layer can be inserted between the copper layer and the gold layer.

As can be seen in FIG. 19(c), the further undercuts 20e, 20f, 20g, 20h introduced in the feet and flanks of the support structure 20 are here also designed for producing the exposed areas 30e, 30f, 30g, 30h, which bring about the electrical insulation of the electrically conductive structures 10a, 10b, 10c comprised by the electrical line structure 1 from the substrate 40. By using the coating of the support structure 20 with the electrically conductive material along the projection direction 100, the electrical line transitions 60a, 60b, 60c are formed between the already existing electrically conductive structures 50a, 50b, 50c on the substrate 40 and the electrically conductive structures 10a, 10b, 10c of the electrical line structure 1. The electrically conductive structures 10a, 10b, 10c here are also routed upwards via the ramp structure, wherein in all cross-sectional planes along the line structure 1, the electrically conductive structures 10a, 10b, 10c initially remain insulated from one another, and wherein at the peak of the ramp the two outer electrically conductive structures 10a, 10c after the shaping of the slots are centrally combined with the central electrically conductive structure 10b, designed as a signal conductor, within a cross-sectional plane, thereby forming a dipole antenna. With a correct design, an efficient matching of the line impedance of the electrical line structure 1 to the wave resistance of free space and thus efficient radiation of the dipole antennas thereby generated can be achieved.

Also in this exemplary embodiment, additional shading structures 70, 71 are used to enable an electrical connection of the electrically conductive structures 10a, 10b, 10c of the electrical line structure 1 to the already existing electrically conductive structures 50a, 50b, 50c without producing a short circuit between the electrically conductive structures 10a, 10b, 10c or the already existing electrically conductive structures 50a, 50b, 50c to the substrate 40 and/or to the electrically conductive structure 11a, 11b, 11c formed on the substrate 40 as a “by-product”.

FIG. 19(c) schematically shows the substrate 40 with three dipole antennas after the additional shading structures 70, 71 were removed beforehand. In order to protect the already existing electrically conductive structures 50a, 50b, 50c over the entire surface of the substrate 40 against a short circuit, as in the exemplary embodiment of FIG. 18 a protective layer 75 made of PMMA is also used here, which is removed again with PGMEA in a lift-off process.

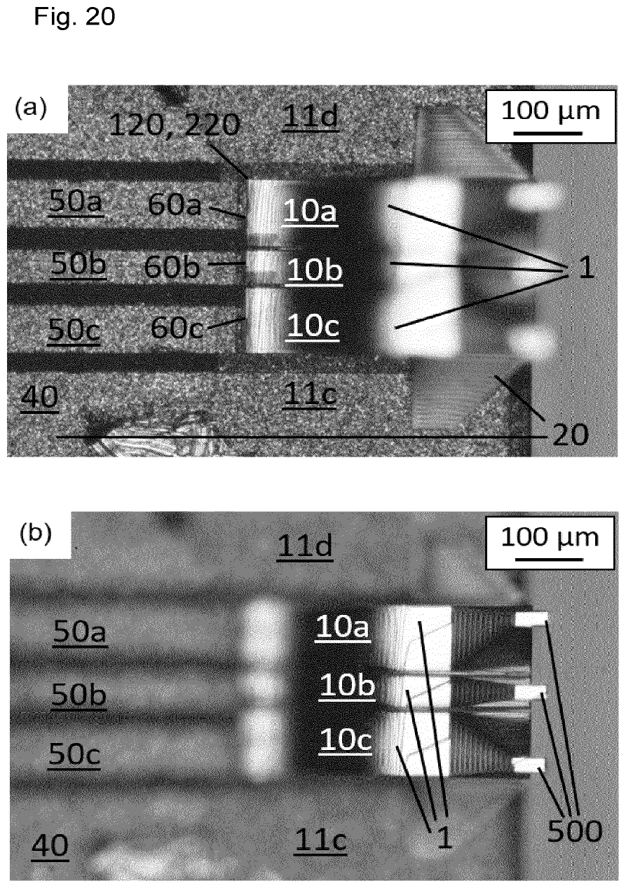

FIG. 20 shows, in the form of microscope images, a further exemplary embodiment of the electrical line arrangement according to the invention according to FIG. 16 as an electrical probe tip, in particular for contacting to RF circuits. For further details reference is made to the description of FIG. 16.

FIG. 20 shows the electrical line arrangement comprising the substrate 40, which comprises a conventionally manufactured coplanar line consisting of three existing electrically conductive structures 50a, 50b, 50c, wherein two of the existing electrically conductive structures 50a, 50c can be at the same electrical potential. The substrate 40 comprises—analogous to the structure sketched in FIG. 9—in each case in a second subregion 220, an insulating support body made of aluminum oxide (Al₂O₃) with a layer thickness of 625 μm, and a conductive region 320 which was produced on the insulating support body by using a gold layer with a layer thickness of 3 μm. The already existing electrically conductive structures 50a, 50b, 50c were produced by structuring this gold layer, for example by using a conventional lithography process or a laser ablation process. To produce the electrical probe tip, here the first subregion 120 of the carrier structure 20 was also structured by using a two-photon lithography process. Subsequently, the support structure 20 was coated with the electrically conductive material by using a PVD process along the projection direction 100 according to FIG. 16 at an angle of 90° to the surface of the substrate 40. The side walls of the slits introduced into the support structure 20 between the surfaces to be coated are provided—analogous to the exemplary embodiments according to FIGS. 18 and 19—with undercuts 20a, 20b, 20c, 20d, 20e, 20f. The undercuts 20a, 20b, 20c, 20d, 20e, 20f here are also designed sufficiently deep that the electrical line structure 1, which comprises the electrically conductive structures 10a, 10b, 10c is either not affected by the electrically conductive structures 11a, 11b, 11c, 11d generated as a “by-product”—analogous to the illustration in FIG. 6—or only insignificantly or in a known manner that must be taken into account during the execution. The coating on the support structure 20, which is implemented for the most part as a copper layer, here also has a total layer thickness of about 600 nm along the projection direction 100. A thin titanium layer serves as an adhesion promoter between the support structure 20 and the copper layer; for passivation relative to the environment, a thin gold layer is applied as an outer layer, wherein here also another thin titanium layer can be inserted between the copper layer and the gold layer.

By using the coating of the support structure 20 with the electrically conductive material along the projection direction 100, the electrical line transitions 60a, 60b, 60c are formed between the already existing electrically conductive structures 50a, 50b, 50c on the substrate 40 and the electrically conductive structures 10a, 10b, 10c of the electrical line structure 1. The electrically conductive structures 10a, 10b, 10c, which remain insulated in all cross-sectional planes along the line structure 1, are here also routed upwards via the ramp structure and converge there at a specified distance in order to form contact elements 500. The contact elements 500 in this case are in the form of pyramid-frustum-like structures.

Also in this exemplary embodiment, additional shading structures 70 are used to enable an electrical connection of the electrically conductive structures 10a, 10b, 10c of the electrical line structure 1 to the already existing electrically conductive structures 50a, 50b, 50c without producing a short circuit between the electrically conductive structures 10a, 10b, 10c or the already existing electrically conductive structures 50a, 50b, 50c to the substrate 40 and/or to the electrically conductive structure 11a, 11b, 11c, 11d formed on the substrate 40 as a “by-product”. In order to protect the already existing electrically conductive structures 50a, 50b, 50c over the entire surface of the substrate 40 against a short circuit—as in the exemplary embodiments of FIGS. 18 and 19—a protective layer 75 made of PMMA is also used here, which is removed with PGMEA in a lift-off process.

In addition to the exemplary embodiments illustrated, further embodiments are possible. The use of a lithography process with significantly larger write-fields and at the same time still sufficiently high lateral resolution in the micrometer range, such as the projection micro-stereolithography technique (PμSL), allows a complete covering of the substrate surface 40 as protection during the coating and dispenses with the complex lift-off process using PMMA and PGMEA used hitherto. The production of large-area protective structures directly together with the support structure 20 and the additional shading structures 70—according to FIG. 12—in the same lithography step results in a significant time saving and a considerable simplification of the method and, by dispensing with the application of chemicals to the substrate 40 and the support structure 20, in particular of the first subregion 120, enables extensive protection of sensitive components and thus much greater freedom in the choice of the material for the support structure 20.

List of reference signs

| | |
|---|---|
| 1 | electrical line structure |
| 10a-10g | electrically conductive structure |
| 11a-11f | additional electrically conductive structure |
| 15 | via |
| 20 | support structure (for the electrical line structure) |
| 20a-20h | undercut (in the support structure) |
| 25 | insulating coating |
| 26 | isotropic coating with protective material |
| 30a-30h | shaded area on support structure; “exposed areas” |
| 35, 36 | planes running parallel to one another |
| 40, 41 | substrate (part of the support structure) |
| 50a-50c, 51a-51c | existing electrical line structure |
| 60a-60c, 61a-61c | electrical line transition |
| 70, 71 | additional shading structure |
| 75 | protective layer |
| 80 | field lines of an electric field; “mode” |
| 100 | projection direction p |
| 105 | divergence of the evaporation beams emitted by the evaporation |
| | source around the defined projection direction p |
| 120 | first subregion of the support structure (generated by a free-form |
| | microstructuring process) |
| 220 | (electrically insulating) second subregion of the support structure |
| 320 | (electrically conductive) subregion of the substrate |
| 500 | contact element |
| 600 | mechanical protective structure |
| 1015 | point P on the surface of the support structure |
| 1016 | half-line g opposite the direction of projection p |
| 1020 | overhang (subregion of the support structure) |
| 1030 | sections of the half-line located inside the support structure |
| 1031 | connecting line PP′ located outside the support structure |
| 1040 | shaded area |
| 2000 | monitor structure |
| 2100 | viewing direction |
| 2200 | indicator structure |
| 2300 | direction of approach |
| 2400 | Deformation |

1. A method for producing an electrical line arrangement, comprising the following steps:
a) producing a support structure, wherein at least one first subregion of the support structure is generated by using a freeform microstructuring method, wherein at least one second subregion of the support structure comprises an electrically insulating material, and wherein the support structured has at least one undercut with respect to a projection direction; and
b) producing at least one electrical line structure by coating the support structure with at least one electrically conductive material, wherein the coating comprises at least one spatially directed coating process, which is oriented along the projection direction, aligned with the at least one undercut.

2. The method of claim 1, wherein the coating of the support structure comprises at least one spatially directed coating process using at least two electrically conductive materials that are different from each other.

3. The method of claim 1, wherein a thickness of the at least one electrical line structure comprising the electrically conductive structures is increased by galvanic growth.

4. The method of claim 1, wherein the at least one electrical line structure is produced in such a way that at least one electrically conductive structure is formed, which is electrically insulated by using at least one exposed area, generated by the at least one undercut, relative to an additional electrically conductive structure adjacent to the at least one electrically conductive structure within a cross-sectional plane of the at least one electrical line structure.

5. (canceled)

6. The method of claim 1, wherein the production of the at least one electrical line structure is selected from the production of
a microstrip line comprising the production of a single structure which is electrically conductive in all cross-sectional planes along the at least one electrical line structure;
a slotted line comprising the production of two electrically conductive structures, which are electrically insulated from one another in all cross-sectional planes along the at least one electrical line structure;
a coplanar line comprising the production of three electrically conductive structures, which are electrically insulated from one another in all cross-sectional planes along the at least one electrical line structure;
an antenna, comprising the production of at least one electrically conductive structure, which in interaction with the at least one exposed area generated by the at least one undercut, is configured to provide a transition of an electrical signal bound to the at least one electrically conductive structure to a free-wave space;
an electrical line coupler comprising the production of three electrically conductive structures which are electrically insulated from one another in all cross-sectional planes along the at least one electrical line structure, two of the electrically conductive structures being placed at different electrical potentials from each other, wherein a distance between the two electrically conductive structures is chosen in such a way that a cross-coupling of an electric field from the one electrically conductive structure to the other electrically conductive structure is adjusted via the third electrically conductive structure;
an electrical probe tip having at least one contact element suitable for contacting corresponding contact surfaces;
an electrical connecting element between at least two electrical line structures, arranged on separate substrates, wherein the support structure comprises the at least two substrates and the first subregion;
an interdigital capacitance comprising a plurality of electrically conductive structures, which are arranged alternately in two different planes running parallel to each other.

7. The method of claim 6, wherein in method step a) additional mechanical protective structures or monitor structures are generated, which are designed to prevent unwanted mechanical damage to the electrical probe tip.

8. The method of claim 1, wherein the at least one undercut, is introduced into the support structure in such a way that an effective permittivity of a mode guided in the at least one electrical line structure is continuously adjusted along a direction of propagation of the mode.

9. (canceled)

10. The method of claim 1, wherein the free-form microstructuring method comprises producing the first subregion of the support structure from a plurality of individual layers, the first subregion of the support structure being constructed from more than 10 layers.

11. The method of claim 1, wherein the support structure is the produced by using a multiphoton polymerization process or a stereo-lithography process.

12. The method of claim 1, wherein a cross-section of the at least one electrical line structure varies along the direction of propagation of the electromagnetic signal or follows a non-planar trajectory which is specified by a non-planar shape of the support structure.

13. The method of claim 1, wherein the first subregion of the support structure and the second subregion of the support structure
mutually comprise each other in whole or in part; or
are disjoint or non-intersecting; or
at least partially overlap; or
are identical.

14. The method of claim 1, wherein an electrical line transition is formed between at least one already existing electrical line structure and the at least one electrical line structure.

15. The method of claim 14, wherein at least one additional shading structure is produced at the at least one electrical line transition in such a way that, when coating the support structure by using the electrically conductive material along the projection direction
at least one additional electrically conductive connection is formed between the at least two already existing electrical line structures and the at least one electrical line structure; or
the at least two existing electrical line structures remain electrically insulated from each other.

16. The method of claim 15, wherein the at least one additional shading structure or a protective layer is applied to further parts of the substrate in such a way that the further parts of the substrate are protected from coverage with the conductive material.

17. The method of claim 15, wherein the at least one additional shading structure or the protective layer is produced by using the free-form microstructuring method, in particular selected from a multiphoton polymerization process or a projection lithography process.

18. The method of claim 15, wherein the at least one additional shading structure or the protective layer is removed after the coating of the support structure, in particular by using a lift-off process or by peeling off the at least one additional shading structure.

19. An electrical line arrangement, comprising:
a support structure comprising
at least one first subregion, designed as a three-dimensional free-form structure and produced using a free-form microstructuring process, and
a second subregion comprising an electrically insulating material, wherein the support structure has at least one undercut with respect to a projection direction; and
at least one electrical line structure applied on the support structure as a coating by using at least one spatially directed coating process with at least one electrically conductive material along the projection direction aligned to the at least one undercut.

20. The electrical line arrangement of claim 19, wherein the coating of the support structure comprises at least two electrically conductive materials that differ from each other.

21. (canceled)

22. The electrical line arrangement of claim 19, wherein the free-form microstructuring method comprises producing the first subregion of the support structure from a plurality of individual layers, wherein the first subregion of the support structure is constructed of more than 10 layers.

23. The electrical line arrangement of claim 19, wherein the at least one electrical line structure comprises at least one electrically conductive structure, which is electrically insulated by using at least one exposed area, generated by the at least one undercut, relative to a further electrically conductive structure adjacent to the at least one electrically conductive structure within a cross-sectional area of the at least one electrical line structure.

24. The electrical line arrangement of claim 19, wherein the support structure comprises a substrate.

25. The electrical line arrangement of claim 19, wherein the at least one electrical line structure is selected from:
a microstrip line comprising a single structure which is electrically conductive in all cross-sectional planes along the at least one electrical line structure;
a slotted line comprising two electrically conductive structures, which are electrically insulated from one another in all cross-sectional planes along the at least one electrical line structure;
a coplanar line comprising three electrically conductive structures which are electrically insulated from one another in all cross-sectional planes along the at least one electrical line structure;
an antenna, comprising the production of at least one electrically conductive structure, which in interaction with the at least one exposed area generated by the at least one undercut is configured to provide a transition of an electrical signal bound to the at least one electrically conductive structure to a free-wave space;
an electrical line coupler comprising three electrically conductive structures which are insulated from one another in all cross-sectional planes along the at least one electrical line structure, two of the electrically conductive structures being placed at different electrical potentials from each other, wherein a distance between the two electrically conductive structures is chosen in such a way that a cross-coupling of an electric field from the one electrically conductive structure to the other electrically conductive structure is adjusted via the third electrically conductive structure;
an electrical probe tip having at least one contact element suitable for contacting corresponding contact surfaces;
an electrical connecting element between at least two electrical line structures arranged on separate substrates, wherein the support structure comprises the at least two substrates and the first subregion; or
an interdigital capacitance comprising a plurality of electrically conductive structures, which are arranged alternately in two different planes running parallel to each other and wherein these can be at different potentials.

26. The electrical line arrangement of claim 25, comprising additional mechanical protective structures or monitor structures, which are designed to prevent unwanted mechanical damage to the electrical probe tip.

27. The electrical line arrangement of claim 19, wherein the undercuts in the support structure are configured in such a way that an effective permittivity of a mode guided in the at least one electrical line structure is continuously adjusted along a direction of propagation of the mode.

28. (canceled)

29. The electrical line arrangement of claim 19, wherein a cross-section of the at least one electrical line structure varies along the direction of propagation of the electromagnetic signal or follows a non-planar trajectory which is specified by a non-planar shape of the support structure.

30. The electrical line arrangement of claim 19, wherein the first subregion of the support structure and the second subregion of the support structure
mutually comprise each other in whole or in part; or
are disjoint or non-intersecting; or
at least partially overlap; or
are identical.

31. The electrical line arrangement of claim 19, comprising at least one additional shading structure or a protective layer, which are applied to further parts of the substrate in such a way that the further parts of the substrate are protected from covering with the conductive material.
